(19) United States
(12) Patent Application Publication
(10) Pub. No.: US 2026/0090202 A1
(43) Pub. Date: Mar. 26, 2026

(54) COMPOSITION, CURED PRODUCT OF THE COMPOSITION, DISPLAY DEVICE INCLUDING THE COMPOSITION, AND METHOD OF MANUFACTURING THE DISPLAY DEVICE

(71) Applicants: Samsung Display Co., Ltd., Yongin-Si (KR); Seoul National University R&DB Foundation, Seoul (KR)

(72) Inventors: Shinya Onoue, Yongin-si (KR); Minsang Kwon, Seoul (KR); Yonghwan Kwon, Seoul (KR); Jaeyoung Sim, Yongin-si (KR); Seokju Lee, Seoul (KR); Soyeon Joo, Yongin-si (KR); Daehyun Hwang, Yongin-si (KR); Hyeondeuk Hwang, Yongin-si (KR)

(21) Appl. No.: 19/336,936

(22) Filed: Sep. 23, 2025

(30) Foreign Application Priority Data
Sep. 24, 2024 (KR) 10-2024-0129443

(51) Int. Cl. H10K 59/12; H10K 59/80; H10K 85/60

(52) U.S. Cl. CPC H10K 59/1201; H10K 59/873; H10K 85/631; H10K 85/6572

(57) ABSTRACT

The present disclosure discloses a composition which comprises an initiator including a first compound, a second compound and a third compound, and an acrylic monomer. The present disclosure further discloses a cured product of the composition, a display device including the composition, and a method of manufacturing the display device. According to the present disclosure, a display device including a protective layer may be manufactured quickly and simply using the composition, and may be protected from impacts outside.

### CROSS-REFERENCE TO RELATED APPLICATION

This application is based on and claims priority under 35 U.S.C. § 119 to Korean Patent Application No. 10-2024-0129443, filed on Sep. 24, 2024, in the Korean Intellectual Property Office, the disclosure of which is incorporated by reference herein in its entirety.

### BACKGROUND

### 1. Field

The present disclosure relates to a composition, and a cured product of the composition. The present disclosure relates to a display device including the composition, and a method of manufacturing the display device.

### 2. Description of the Related Art

Electronic devices based on mobility are widely used. As portable electronic devices, tablet PCs, as well as small electronic devices such as mobile phones, have recently been widely used.

Such portable electronic devices include a display device to provide a user with visual information such as images or videos in order to support various functions. Recently, as components required to drive the display device have become smaller, the proportion of the display device in the electronic device has been gradually increasing. Moreover, structures that allow the display device to bend to a certain angle from a flat state are also being developed.

### SUMMARY

Embodiments of the present disclosure include a composition suitable for use as a protective layer on a side and a bending portion of a display panel in a display device and a manufacturing method of the composition that is used to simply and quickly produce the protective layer, and a method of manufacturing the display device including the composition.

Additional aspects will be set forth in the description which follows and will be apparent from the description.

According to an embodiment, a composition includes an initiator including a first compound represented by Formula 1 below, a second compound represented by Formula 2 below and a third compound represented by Formula 3 below, and an acrylic monomer.

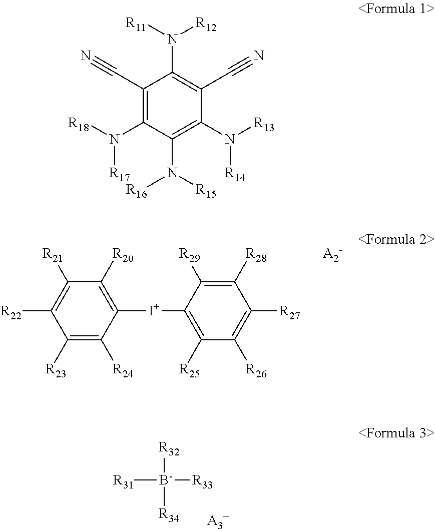

In Formulae 1 to 3, A₂⁻ may be a counter anion, A₃⁺ may be a counter cation. Each of R₁₁ to R₁₈, R₂₀ to R₂₉ and R₃₁ to R₃₄ may be independently selected from a group consisting of hydrogen (—H), deuterium (-D), fluorine (—F), chlorine (—Cl), bromine (—Br), iodine (—I), a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂).
Adjacent two or more groups among R₁₁ to R₁₈ may be optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ.
Adjacent two or more groups among R₂₀ to R₂₉ may be optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ.
Adjacent two or more groups among R₃₁ to R₃₄ may be optionally combined to each other to form a C₅-C₃₀ carbocyclic group unsubstituted or substituted with at least one R₁₀, or a C₁-C₃₀ heterocyclic group unsubstituted or substituted with at least one R₁₀ₐ.

R₁₀ₐ may be selected from a group consisting of deuterium (-D), fluorine (—F), chlorine (—Cl), bromine (—Br), iodine (—I), a hydroxyl group, a cyano group or a nitro group, a C₁-C₆₀ alkyl group, a C₂-C₆₀ alkenyl group, a C₂-C₆₀ alkynyl group, or a C₁-C₆₀ alkoxy group, each of which is unsubstituted or substituted with deuterium (-D), fluorine (—F), chlorine (—Cl), bromine (—Br), iodine (—I), a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁) or —S(═O)₂(Q₁₁), —P(═O)(Q₁₁)(Q₁₂), a C₃-C₆₀ carbocyclic group, a C₁-C₆₀ heterocyclic group, a C₆-C₆₀ aryloxy group, or a C₆-C₆₀ arylthio group, each of which is unsubstituted or substituted with deuterium (-D), fluorine (—F), chlorine (—Cl), bromine (—Br), iodine (—I), a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁) or —S(═O)₂(Q₂₁), —P(═O)(Q₂₁)(Q₂₂), and —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁) or —P(═O)(Q₃₁)(Q₃₂).

Each of Q₁ to Q₃, Q₁₁ to Q₁₃, Q₂₁ to Q₂₃, and Q₃₁ to Q₃₃ may be independently selected from a group consisting of hydrogen (—H), deuterium (-D), fluorine (—F), chlorine (—Cl), bromine (—Br), iodine (—I), a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group unsubstituted or substituted with deuterium, fluorine, a cyano group, a C₁-C₆₀ alkyl group, a C₁-C₆₀ alkoxy group, a phenyl group or a biphenyl group, and a C₁-C₆₀ heterocyclic group unsubstituted or substituted with deuterium, fluorine, a cyano group, a C₁-C₆₀ alkyl group, a C₁-C₆₀ alkoxy group, a phenyl group or a biphenyl group.

According to an embodiment, a cured product of the composition is formed by emitting light to the composition.

According to an embodiment, a display device includes a display panel. The display panel may include a substrate including a first area, a second area, and a bending area connecting the first area to the second area and being bent, a first protective layer disposed on at least one portion of an edge of the substrate, a second protective layer disposed inside a bent portion of the substrate, and the first protective layer and the second protective layer include the composition.

According to an embodiment, a method of manufacturing a display device includes disposing a display panel, at least a part of which is bent, on a second jig, disposing a first jig and a mold on the display panel to form a space adjacent to at least one edge of the display panel, supplying the composition into the space, and curing the composition by irradiating light with a peak top wavelength in a range from about 450 nm to about 530 nm.

### BRIEF DESCRIPTION OF THE DRAWINGS

The above and other aspects, features, and advantages of the present disclosure will become more apparent with reference to the following description taken in conjunction with the accompanying drawings.

FIG. 1 is a schematic perspective view of a display device according to an embodiment.

FIG. 2 is a schematic exploded perspective view of the display device shown in FIG. 1.

FIG. 3A is a schematic cross-sectional view of a display panel taken along a line III-III′ of FIG. 2.

FIG. 3B is an enlarged cross-sectional view of area A shown in FIG. 3A.

FIG. 4 is a schematic plan view of the display panel illustrated in FIG. 2.

FIG. 5 is a schematic perspective view illustrating a portion of the display panel, shown in FIG. 4, is in a bending state.

FIG. 6 is a cross-sectional view taken along a line VI-VI′ of FIG. 4.

FIG. 7 is a schematic perspective view of a manufacturing apparatus for a display device according to an embodiment.

FIG. 8 is a schematic cross-sectional view of the manufacturing apparatus for the display device illustrated in FIG. 7.

FIGS. 9A to 9C are schematic cross-sectional views illustrating a method of manufacturing a display device according to an embodiment.

FIG. 10 is a schematic cross-sectional view illustrating a part of a display device according to an embodiment.

FIGS. 11A and 11B show absorption spectra of Comparative Compound 1 and Compound 1, respectively.

### DETAILED DESCRIPTION

Hereinafter, specific embodiments of the present disclosure are explained in detail with reference to the accompanying drawings. Like numerals refer to like elements throughout. In this regard, embodiments of the present disclosure may have different forms and should not be construed as being limited to the descriptions set forth herein. Accordingly, the embodiments are merely described below, by referring to the drawings, to explain aspects of the present description. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

As the present disclosure allows for various changes and numerous embodiments, particular embodiments will be illustrated in the drawings and described in detail in the written description. Effects and features of the present disclosure, as well as the method for achieving the effects and features will become clear by referring to embodiments described below in connection with the accompanying drawings. However, it should be noted that the present disclosure is not limited to the following embodiments and may be implemented in various forms.

Hereinafter, embodiments will be described in detail with reference to the accompanying drawings. In the drawings, like reference numerals denote like elements or components having substantially same functions, and duplicate descriptions will be omitted.

In the following embodiments, terms “first,” “second,” etc. are used to distinguish one element from other elements and, therefore, the elements are not limited by the terms.

An expression used in the singular encompasses the expression of the plural unless it has a clearly different meaning in the context.

In the following embodiments, it is to be understood that the terms “include” or “have” are intended to indicate the existence of elements disclosed in the specification, and are not intended to preclude the possibility that one or more other elements may exist or may be added.

In the following embodiments, it will be understood that when one portion such as membrane, region, or element, is referred to as being “on” another membrane, region, or element, it may be directly on the other membrane, region, or element, or intervening membrane, region, or element may also be present therebetween.

Also, sizes of elements in the drawings may be exaggerated or reduced for convenience of explanation. For example, since sizes and thicknesses of elements in the drawings are arbitrarily illustrated for convenience of explanation, the following embodiments are not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be orthogonal to each other, but may not be orthogonal to one another facing different directions.

In the case where some embodiments may be implemented in a different manner, the processes may be performed in an order different from that described herein. For example, two processes described in succession may be performed substantially simultaneously or may be performed in the reverse order to that described herein.

### [Composition]

A composition according to an embodiment includes an initiator including a first compound represented by Formula 1 below, a second compound represented by Formula 2 below, and a third compound represented by Formula 3 below, and an acrylic monomer.

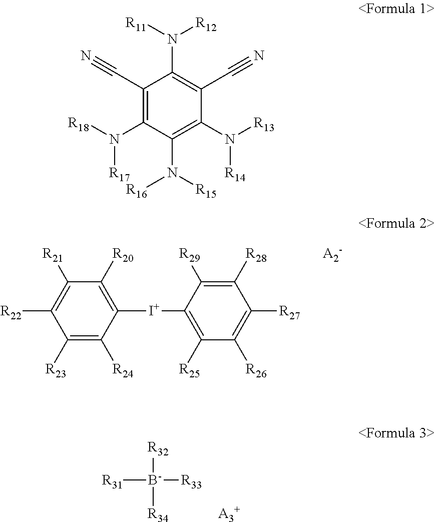

In Formulae 1 to 3, A₂⁻ is a counter anion, A₃⁺ is a counter cation. Each of Ru to R₁₈, R₂₀ to R₂₉ and R₃₁ to R₃₄ is independently selected from a group consisting of hydrogen (—H), deuterium (-D), fluorine (—F), chlorine (—Cl), bromine (—Br), iodine (—I), a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁) and —P(═O)(Q₁)(Q₂).

Adjacent two or more groups among R₁₁ to R₁₈ are optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ. Adjacent two or more groups among R₂₀ to R₂₉ are optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ. Adjacent two or more groups among R₃₁ to R₃₄ are optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ.

According to an embodiment, R₁₀ₐ may be deuterium (-D), fluorine (—F), chlorine (—Cl), bromine (—Br), iodine (—I), a hydroxyl group, a cyano group, or a nitro group. However, the present disclosure may not be limited thereto. For example, R₁₀ₐ may be a C₁-C₆₀ alkyl group, a C₂-C₆₀ alkenyl group, a C₂-C₆₀ alkynyl group, or a C₁-C₆₀ alkoxy group, each of which is unsubstituted or substituted with deuterium, fluorine, chlorine, bromine, iodine, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof. For example, R₁₀ₐ may be a C₃-C₆₀ carbocyclic group, a C₁-C₆₀ heterocyclic group, a C₆-C₆₀ aryloxy group, or a C₆-C₆₀ arylthio group, each of which is unsubstituted or substituted with deuterium, fluorine, chlorine, bromine, iodine, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof. For example, R₁₀ₐ may be —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Each of Q₁ to Q₃, Q₁₁ to Q₁₃, Q₂₁ to Q₂₃, and Q₃₁ to Q₃₃ is independently selected from a group consisting of hydrogen, deuterium, fluorine, chlorine, bromine, iodine, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group unsubstituted or substituted with deuterium, fluorine, a cyano group, a C₁-C₆₀ alkyl group, a C₁-C₆₀ alkoxy group, a phenyl group or a biphenyl group, or a C₁-C₆₀ unsubstituted or substituted with deuterium, fluorine, a cyano group, a C₁-C₆₀ alkyl group, a C₁-C₆₀ alkoxy group, a phenyl group or a biphenyl group.

According to an embodiment, in Formula 1, each of R₁₁ to R₁₈ is independently selected from a group consisting of a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₆-C₆₀ aryl group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, and a monovalent non-aromatic condensed heteropolycyclic group unsubstituted or substituted with at least one R₁₀ₐ.

According to an embodiment, the first compound may be represented by one of Formulae 1-1 and 1-2 below.

### <Formula 1-1>

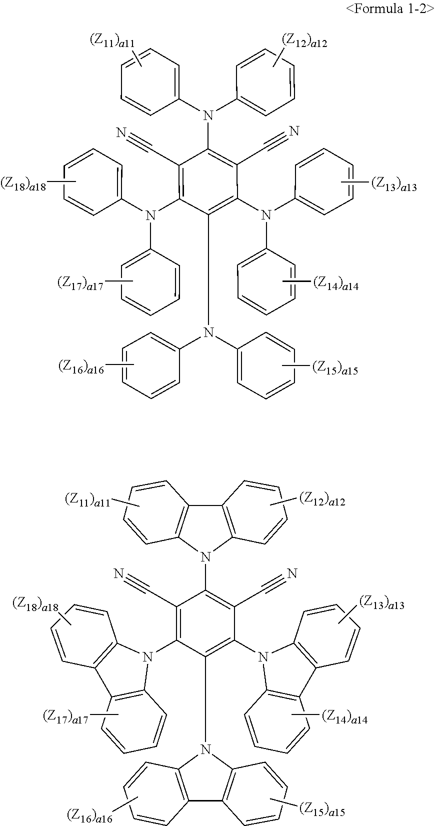

In Formulae 1-1 an 1-2, each Z₁₁ to Z₁₈ is independently selected from a group consisting of hydrogen or R₁₀ₐ, as described above, and each of a11 to a18 is an integer from 1 to 4.

According to an embodiment, in Formula 2, each of R₂₀ to R₂₉ is independently selected from a group consisting of hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, and a C₁-C₆₀ alkoxy group unsubstituted or substituted with at least one R₁₀ₐ.

According to an embodiment, the first compound may be one selected from the compounds of Group 1 below.

### <Group 1>

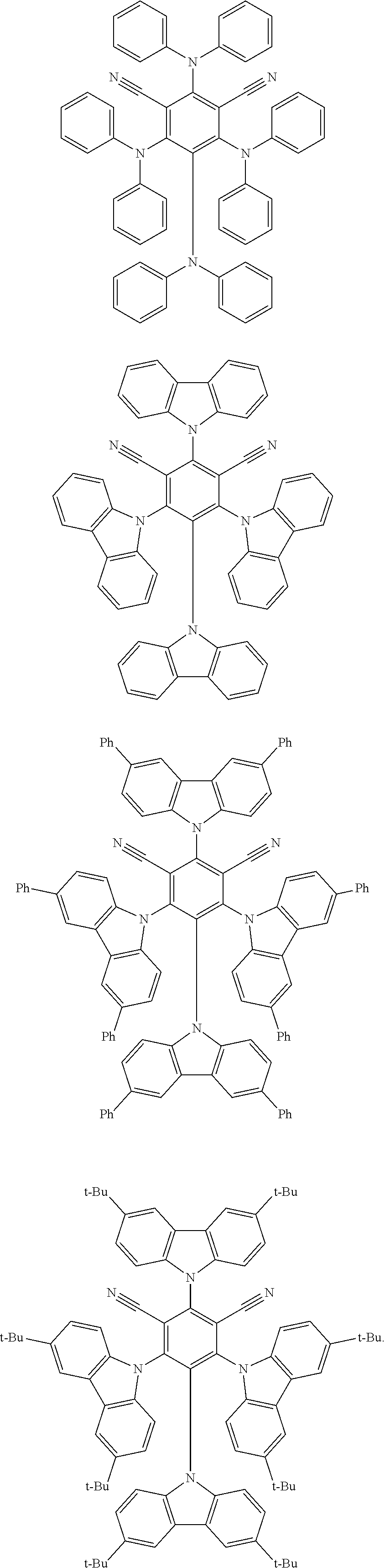

In Group 1, Ph is a phenyl group, and t-Bu is a t-butyl group.

According to an embodiment, in Formula 2, A₂⁻ may include a fluorine atom.

According to an embodiment, in Formula 2, A₂⁻ may be SbF₆⁻, PF₆⁻, —B(C₆F₅)₄, PF₆⁻, BF₆⁻, CF₃(CF₂)₃SO₃⁻, CF₃SO₃⁻, AsF₆⁻, Cl⁻, or Al(OC(CF₃)₃)₄⁻, but is not limited thereto. For example, in Formula 2, A₂⁻ may be ⁻B(C₆F₅)₄.

According to an embodiment, the second compound may be one selected from the compounds of Group 2 below, but is not limited thereto.

### <Group 2>

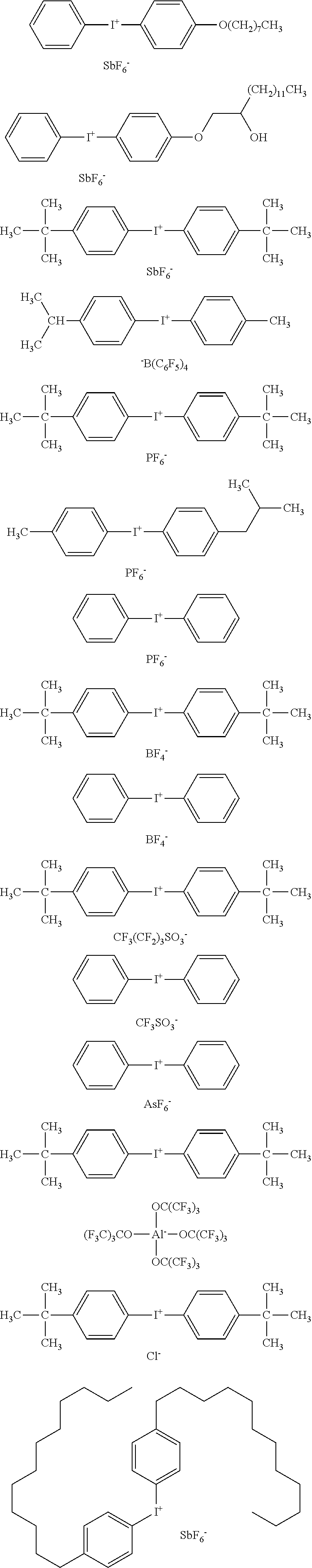

According to an embodiment, in Formula 3, each of R₃₁ to R₃₄ may be independently selected from a group consisting of a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₆-C₆₀ aryl group unsubstituted or substituted with at least one R₁₀ₐ, and a C₁-C₆₀ heteroaryl group unsubstituted or substituted with at least one R₁₀ₐ.

According to an embodiment, in Formula 3, R₃₁ to R₃₃ may be each independently a C₆-C₆₀ aryl group unsubstituted or substituted with at least one R₁₀ₐ or a C₁-C₆₀ heteroaryl group unsubstituted or substituted with at least one R₁₀ₐ.

For example, in Formula 3, R₃₁ to R₃₃ may be each independently a phenyl group or a naphthyl group, each of which is unsubstituted or substituted with at least one R₁₀ₐ.

According to an embodiment, in Formula 3, A₃⁺ may be a cationic organic compound.

According to an embodiment, in Formula 3, A₃⁺ may be [P(R₃₁ₐ)(R_{31b})(R_{31c})(R_{31d})]⁺ or [N(R₃₂ₐ)(R_{32b})(R_{32c})(R_{32d})]⁺. In this example, each of R₃₁ₐ, R_{31b}, R_{31c}, R_{31d}, R₃₂ₐ, R_{32b}, R_{32c} and R_{32d} may be independently selected from a group consisting of a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, and a C₁-C₆₀ heterocyclic group unsubstituted or substituted with at least one R₁₀ₐ.

For example, in Formula 3, A₃⁺ may be one selected from the compounds of Group 3A below.

### <Group 3A>

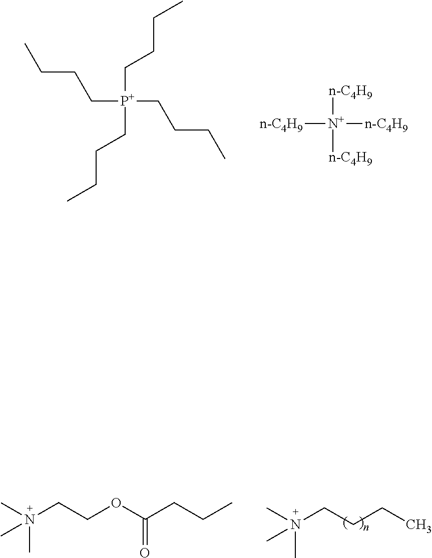

According to an embodiment, the third compound may be one selected from the compounds of Group 3 below.

### <Group 3>

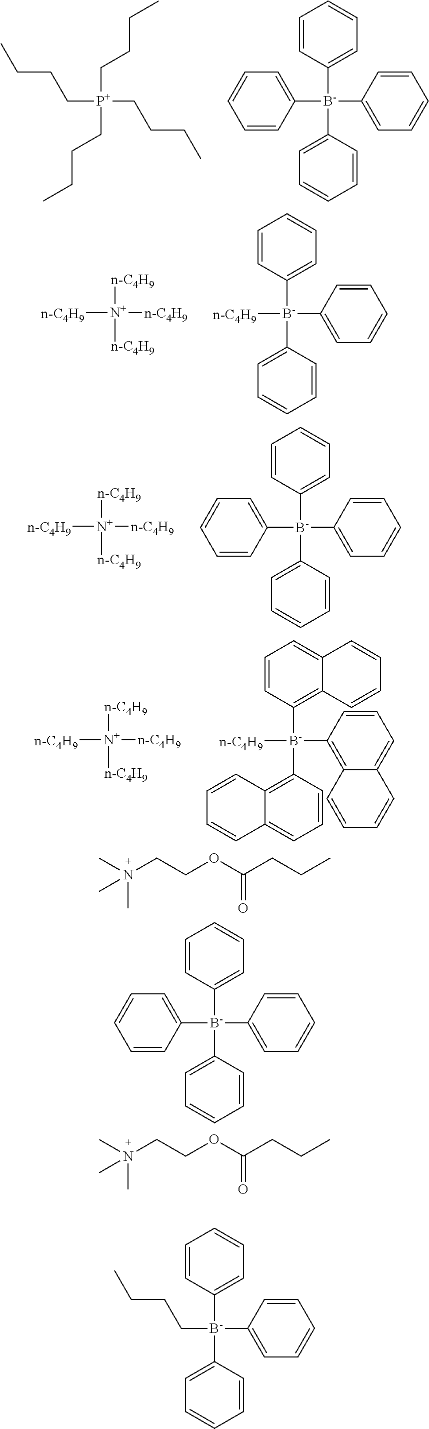

According to an embodiment, a concentration of the first compound in the composition may be greater than 0 ppm, and equal to or less than 500 ppm.

According to an embodiment, a concentration of the second compound in the composition may be equal to or more than 500 ppm, and equal to or less than 10,000 ppm.

According to an embodiment, a concentration of the third compound in the composition may be equal to or more than 500 ppm, and equal to or less than 10,000 ppm.

According to an embodiment, the acrylic monomer may include a compound represented by Formula 4 below.

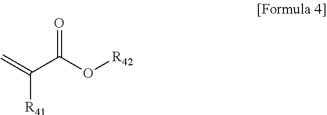

In Formula 4, R₄₁ and R₄₂ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂)-.

### [Cured Product of the Composition]

According to an embodiment, a cured product formed by emitting light to the composition according to the present disclosure, as described above, may be provided.

According to an embodiment, a peak top wavelength, i.e., a central wavelength, of the light emitted to the composition may be 450 nm or more, 451 nm or more, 452 nm or more, 453 nm or more, 454 nm or more, 455 nm or more, 456 nm or more, 457 nm or more, 458 nm or more, 459 nm or more, or 460 nm or more.

According to an embodiment, the peak top wavelength of the light emitted to the composition may be 500 nm or less, 499 nm or less, 498 nm or less, 497 nm or less, 496 nm or less, 495 nm or less, 494 nm or less, 493 nm or less, 492 nm or less, 491 nm or less, or 490 nm or less.

According to an embodiment, a Young's ratio of the cured product of the composition may be equal to or more than 200 MPa.

According to an embodiment, a Young's ratio of the cured product of the composition may be equal to or less than 3,000 MPa.

According to an embodiment, an elongation of the cured product of the composition may be from about 5% to about 100%.

According to an embodiment, a glass transition temperature T_{g} of the cured product of the composition may be from about 20° C. to about 100° C.

As used herein, the C₃-C₆₀ carbocyclic group may refer to a cyclic group containing 3 to 60 carbon atoms, wherein the ring-forming atoms include only carbon atoms, and the C₁-C₆₀ heterocyclic group may refer to a cyclic group containing 1 to 60 carbon atoms, wherein the ring-forming atoms include not only carbon atoms but also hetero atoms. Each of the C₃-C₆₀ carbocyclic group and the C₁-C₆₀ heterocyclic group may be a monocyclic group including a single ring or a polycyclic group including two or more rings fused together. For example, the number of the ring-forming atoms of the C₁-C₆₀ heterocyclic group may be 3 to 61.

As used herein, the cyclic group includes both the C₃-C₆₀ carbocyclic group and the C₁-C₆₀ heterocyclic group.

The C₃-C₆₀ carbocyclic group may be i) group T1 or ii) a condensed ring group in which 2 or more group T1s are condensed (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group).

The C₁-C₆₀ heterocyclic group may be i) group T2, ii) a condensed ring group in which 2 or more group T2s are condensed, or iii)) a condensed ring group in which one or more group T2s and one or more group T1s are condensed (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonapthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group).

The group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group.

The group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

The group T3 may be a furan group, a thiophene group, a 1H-pyrrole group, a silole group, or a borole group.

The group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

As used herein, the term cyclic group, C₃-C₆₀ carbocyclic group, C₁-C₆₀ heterocyclic group, π electron-rich C₃-C₆₀ cyclic group, or π electron-deficient nitrogen-containing C₁-C₆₀ cyclic group may be a group condensed to any cyclic group, a monovalent group, or a polyvalent group (e.g., divalent group, trivalent group, and tetravalent group), depending on the structure of the chemical formular in which the term is used. For example, the “benzene group” may be a benzo group, a phenyl group, a phenylene group, or the like, which may be easily understood by those skilled in the art depending on a structure of a chemical formula including the “benzene group”.

For example, examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, or a monovalent non-aromatic condensed heteropolycyclic group. Examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, or a divalent non-aromatic condensed heteropolycyclic group.

As used herein, the C₁-C₆₀ alkyl group may refer to a linear or branched monovalent aliphatic hydrocarbon group including 1 to 60 carbon atoms. Examples of the C₁-C₆₀ alkyl group may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group. As used herein, the C₁-C₆₀ alkylene group may refer to a divalent group having the same structure as that of the C₁-C₆₀ alkyl group.

As used herein, the C₂-C₆₀ alkenyl group may refer to a monovalent hydrocarbon group including at least one carbon-carbon double bond in the middle or at a terminal of the C₂-C₆₀ alkyl group. Examples of the C₂-C₆₀ alkenyl group may include an ethenyl group, a propenyl group, or a butenyl group. As used herein, the C₂-C₆₀alkenylene group may refer to a divalent group having the same structure as that of the C₂-C₆₀ alkenyl group.

As used herein, the C₂-C₆₀ alkynyl group may refer to a monovalent hydrocarbon group including at least one carbon-carbon triple bond in the middle or at a terminal of the C₂-C₆₀ alkyl group. Examples of the C₂-C₆₀ alkynyl group may include an ethynyl group or a propynyl group. As used herein, the C₂-C₆₀ alkynylene group refers to a divalent group having the same structure as that of the C₂-C₆₀ alkynyl group.

As used herein, the C₁-C₆₀ alkoxy group may refer to a monovalent group having a chemical formula of —OA₁₀₁ (where the A₁₀₁ is the C₁-C₆₀ alkyl group). Examples of the C₁-C₆₀ alkoxy group may include a methoxy group, an ethoxy group, or an isopropyloxy group.

As used herein, the C₃-C₁₀ cycloalkyl group may refer to a monovalent saturated hydrocarbon cyclic group containing 3 to 10 carbon atoms. Examples of the C₃-C₁₀ cycloalkyl group may include cyclopropyl group, a cyclobutyl group, a cyclopentyl group, a cyclohexyl group, a cycloheptyl group, a cyclooctyl group, an adamantanyl group, a norbornanyl group (or, bicyclo[2.2.1]heptyl), bicyclo[1.1.1]pentyl, bicyclo[2.1.1]hexyl, or bicyclo[2.2.2]octyl group. As used herein, the C₃-C₁₀ cycloalkylene group may refer to a divalent group having the same structure as that of the C₃-C₁₀ cycloalkyl group.

As used herein, the C₁-C₁₀ heterocycloalkyl group may refer to a monovalent cyclic group containing 1 to 10 carbon atoms and further including at least one hetero atom, as a ring-forming atom. Examples of the C₁-C₁₀ heterocycloalkyl group may include a 1,2,3,4-oxatriazolidinyl group, a tetrahydrofuranyl group, or a tetrahydrothiophenyl group. As used herein, the C₁-C₁₀ heterocycloalkylene group may refer to a divalent group having the same structure as that of the C₁-C₁₀ heterocycloalkyl group.

As used herein, the C₃-C₁₀ cycloalkenyl group may refer to a monovalent cyclic group containing 3 to 10 carbon atoms and including at least one carbon-carbon double bond within the ring without aromaticity. Examples of the C₃-C₁₀ cycloalkenyl group may include a cyclopentenyl group, a cyclohexenyl group, or a cycloheptenyl group. As used herein, the C₃-C₁₀ cycloalkenylene group may refer to a divalent group having the same structure as that of the C₃-C₁₀ cycloalkenyl group.

As used herein, the C₁-C₁₀ heterocycloalkenyl group may refer to a monovalent cyclic group containing 1 to 10 carbon atoms, which includes at least one hetero atom and carbon atoms, as a ring-forming atom, and has at least one double bond within the ring. Examples of the C₁-C₁₀ heterocycloalkenyl group may include 4,5-dihydro-1,2,3,4-oxatriazolyl group, a 2,3-dihydrofuranyl group, or a 2,3-dihydrothiophenyl group. As used herein, the C₁-C₁₀ heterocycloalkenylene group may refer to a divalent group having the same structure as that of the C₁-C₁₀ heterocycloalkenyl group.

As used herein, the C₆-C₆₀ aryl group may refer to a monovalent group having a carbocyclic aromatic system containing 6 to 60 carbon atoms, and the C₆-C₆₀ arylene group may refer to a divalent group having a carbocyclic aromatic system containing 6 to 60 carbon atoms. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, or an ovalenyl group. In the case where the C₆-C₆₀ aryl group and the C₆-C₆₀ arylene group include two or more rings, the two or more rings may be condensed with each other.

As used herein, the C₁-C₆₀ heteroaryl group may refer to a monovalent group having a heterocyclic aromatic system containing 1 to 60 carbon atoms and further including at least one hetero atom and carbon atoms, as a ring-forming atom, and the C₁-C₆₀ heteroarylene group may refer to a divalent group having a heterocyclic aromatic system containing 1 to 60 carbon atoms and further including at least one hetero atom and carbon atoms, as a ring-forming atom. Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, or a naphthyridinyl group. In the case where the C₁-C₆₀ heteroaryl group and the C₁-C₆₀ heteroarylene group include two or more rings, the two or more rings may be condensed with each other.

As used herein, the monovalent non-aromatic condensed polycyclic group may refer to a monovalent group containing only carbon atoms (e.g., 8 to 60 carbon atoms), as ring-forming atoms, and having non-aromaticity in which two or more rings are condensed with each other. Examples of the monovalent non-aromatic condensed polycyclic group may include an indenyl group, a fluorenyl group, a spiro-bifluorenyl group, a benzofluorenyl group, an indenophenanthrenyl group, or an indenoanthracenyl group. As used herein, the divalent non-aromatic condensed polycyclic group may refer to a divalent group having the same structure as that of the monovalent non-aromatic condensed polycyclic group.

As used herein, the monovalent non-aromatic condensed heteropolycyclic group may refer to a monovalent group (e.g., including 1 to 60 carbon atoms) containing at least one hetero atom in addition to carbon atoms, as a ring-forming atoms, with non-aromaticity in which two or more rings are condensed with each other. Examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, or a benzothienodibenzothiophenyl group. As used herein, the divalent non-aromatic condensed heteropolycyclic group may refer to a divalent group having the same structure as that of the monovalent non-aromatic condensed heteropolycyclic group.

As used herein, the C₆-C₆₀ aryloxy group may be —OA₁₀₂ (wherein A₁₀₂ is the C₆-C₆₀ aryl group), and the C₆-C₆₀ arylthio group is —SA₁₀₃ (wherein A₁₀₃ is the C₆-C₆₀ aryl group).

As used herein, the C₇-C₆₀ arylalkyl group may be -A₁₀₄A₁₀₅ (wherein A₁₀₄ is a C₁-C₅₄ alkylene group, and A₁₀₅ is a C₆-C₅₉ aryl group), and the C₂-C₆₀ heteroaryl alkyl group may be -A₁₀₆A₁₀₇ (wherein A₁₀₆ is a C₁-C₅₉ alkylene group, and A₁₀₇ is a C₁-C₅₉ heteroaryl group).

As used herein, the hetero atom may refer to atoms other than carbon atom. Examples of the hetero atom may include O, S, N, P, Si, B, Ge, Se, or any combination thereof.

As used herein, the “biphenyl group” may refer to “phenyl group substituted with a phenyl group”. The “biphenyl group” may belong to “substituted phenyl group” with a “C₆-C₆₀ aryl group” as a substituent.

As used herein, the “terphenyl group” may refer to “phenyl group substituted with a biphenyl group”. The “terphenyl group” may belong to “substituted phenyl group” with a “C₆-C₆₀ aryl group substituted with a C₆-C₆₀ aryl group” as a substituent.

### [Display Device]

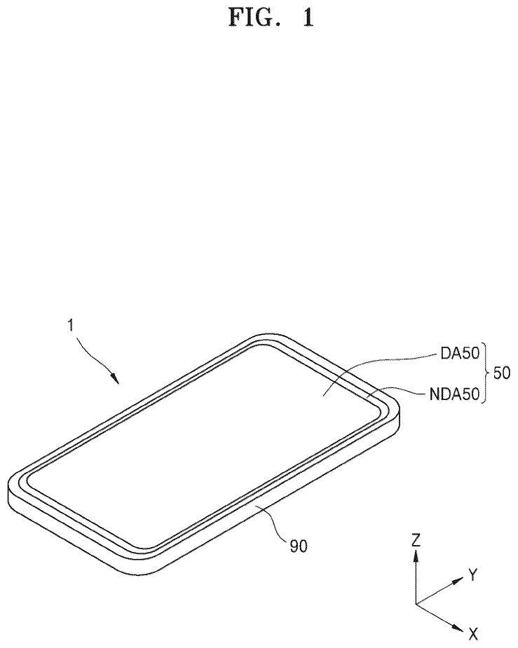

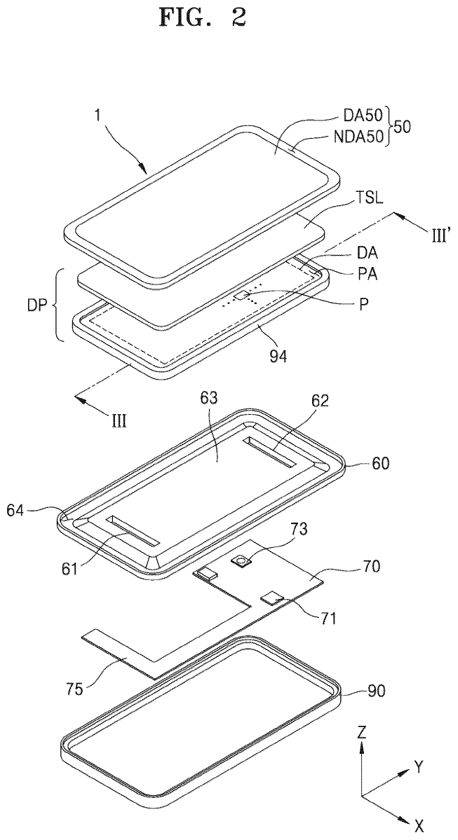

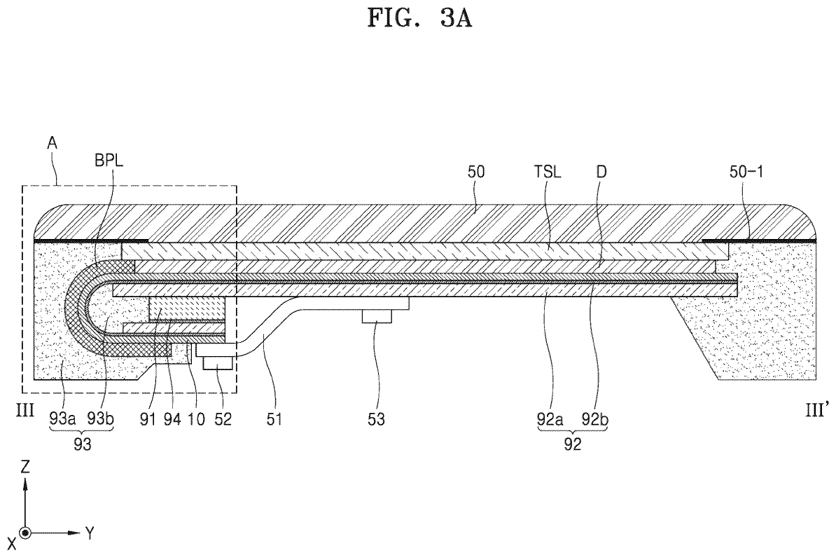

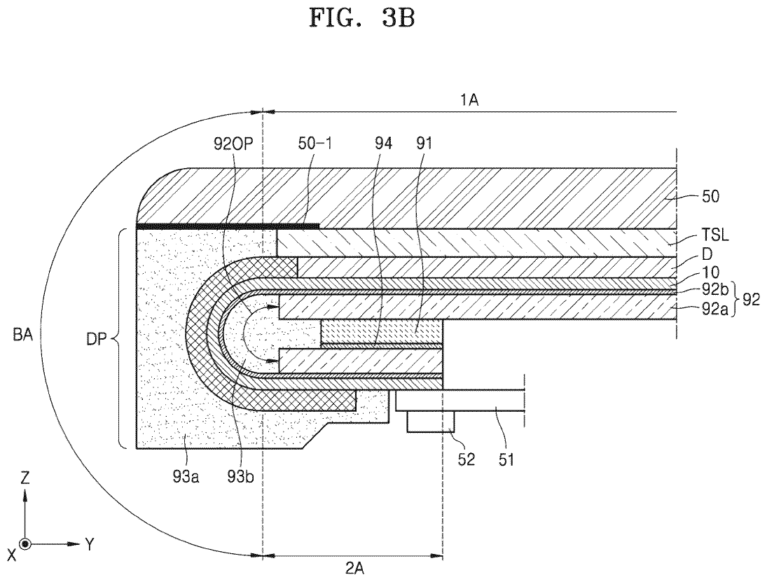

FIG. 1 is a schematic perspective view of a display device according to an embodiment. FIG. 2 is a schematic exploded perspective view of the display device shown in FIG. 1. FIG. 3A is a schematic cross-sectional view of a display panel taken along a line III-III′ of FIG. 2. FIG. 3B is an enlarged cross-sectional view of area A shown in FIG. 3A.

Referring to FIGS. 1, 2, 3A, and 3B, a display device 1, as a device used to display moving images or still image, may be used as a display screen of not only portable electronic devices such as mobile phones, smart phones, tablet personal computers (PCs), mobile communication terminals, electronic notebooks, electronic books, portable multimedia players (PMPs), navigation devices, or ultra mobile PCs (UMPCs), but also various products such as televisions, laptops, monitors, billboards, and internet of things (IOT). The display device 1 may be used in wearable devices such as smart watches, watch phones, glasses type displays, and head mounted displays (HMDs). The display device 1 may be used as a center information display disposed on instrument panels, center fascia or dashboards of vehicles, as a room mirror display replacing side mirrors, as a device for entertainment of backseats of vehicles, or as a display disposed on the rear surface of front seats.

The display device 1 may include a display panel DP, a display circuit board 51, a cover member 50, a bracket 60, a main circuit board 70, and a lower cover 90.

The cover member 50 may be disposed on the top of the display panel DP. In an embodiment, the cover member 50 may cover the top of the display panel DP. Therefore, the cover member 50 may protect the upper surface of the display panel DP.

The cover member 50 may have a light-transmitting cover region DA50 corresponding to a display area DA of the display panel DP and a light-blocking cover region NDA50 corresponding to areas other than the display area DA of the display panel DP. The light-blocking cover region NDA50 may include an opaque material that blocks light. The light-blocking cover region NDA50 may include a pattern that may be shown to a user in the case where an image is not displayed.

The display panel DP may be disposed under the cover member 50. The display panel DP may overlap the light-transmitting cover region DA50 of the cover member 50.

Although not shown in the drawings, the cover member 50 may include a cover window (not shown) and a protection member (not shown). The cover window may include a transparent material. In this regard, the cover window may include glass, a transparent synthetic resin, or the like. The cover window may include at least one layer.

The protection member may be disposed on the upper surface of the cover window to prevent or minimize scratches or the like on the cover window. In an embodiment, an opaque layer 50-1 may be disposed on at least a portion of the cover window and the protection member. In an embodiment, the opaque layer 50-1 may be disposed on the border of the cover window or the border of the protection member. The opaque layer 50-1 may block light and may be disposed on the light-blocking cover region NDA50 of the cover member 50.

The display panel DP may include a display area DA in which an image is displayed, and a peripheral area PA disposed around the display area DA. In the display area DA, sub-pixels P including display elements may be disposed. The sub-pixels P may be provided in plural numbers, and the plurality of sub-pixels P may be disposed to be spaced apart from each other. Each of the plurality of sub-pixels P may emit light with different colors. The display device 1 may provide an image by using light emitted from sub-pixels P disposed in the display area DA, and the peripheral area PA may be a non-display region in which the sub-pixels P are not disposed.

The display panel DP outputs information processed by the display device 1. For example, the display panel DP may display execution screen information of an application running on the display device 1, or a user interface (US) or a graphic user interface (GUI) based on the execution screen information. The display panel DP may include a display layer configured to display a image and a touch sensor layer (TSL) configured to detect a touch input of a user. As a result, the display panel DP may serve not only as one of input devices that provides an input interface between the display device 1 and the user, but also as one of output devices that provides an output interface between the display device 1 and the user.

Hereinafter, an organic light emitting display device will be described as an example of the display device 1 according to an embodiment. However, the display device 1 of the present disclosure is not limited thereto. For example, the display device 1 of the present disclosure may be a display device such as an inorganic light emitting display, an inorganic electroluminescent (EL) display, or a quantum dot light emitting display. For example, an emission layer of a display element included in the display device 1 may include an organic material, an inorganic material, a quantum dot, both an organic material and a quantum dot, or both an inorganic material and a quantum dot.

According to an embodiment, the display panel DP may be a flexible display panel to be easily bendable, foldable, or rollable. For example, the display panel DP may be a foldable display panel that may be folded and unfolded, a curved display panel with a curved display surface, a bended display panel with an area, other than the display surface, being bent, a rollable display panel that may be rolled or unrolled, or a stretchable display panel that may be elongated. For example, the display panel DP may be a rigid display panel that is not easily bent due to rigidity.

The display panel DP may include a substrate 10, a display layer D disposed on the substrate 10, a touch sensor layer TSL disposed on the display layer D, and a protective layer 93 disposed to surround side surfaces of the substrate 10 and the display layer D. According to an embodiment, at least one portion of the substrate 10 may be bendable. The protective layer 93 may include a first protective layer 93a disposed on at least one portion of the edge of the substrate 10 and the display layer D and a second protective layer 93b disposed inside the bent portion of the substrate 10. The first protective layer 93a may be connected to the second protective layer 93b. The second protective layer 93b may be disposed between a first area 1A, a second area 2A, and a bending area BA. Hereinafter, a case where the first protective layer 93a surrounds the entire edge of the substrate 10 will be described in detail for the convenience of description. In the above-described case, the first protective layer 93a may be disposed to surround not only the edge of the substrate 10 but also the outer surface of a bending protection layer BPL.

The protective layer 93 as described above may include a cure product of the composition according to the present disclosure. In this regard, the composition may be cured by light emitted thereto. Particularly, the composition may be cured by light, whose peak top wavelength is in a range from about 450 nm to about 500 nm. If the peak top wavelength of the emitted light is less than 450 nm, the light cannot pass through the substrate 10, so that the second protective layer 93b may not be cured together with the first protective layer 93a. In addition, if light having a peak top wavelength exceeding 500 nm is emitted, the display panel DP may be damaged by the excessive heat caused by the light having a peak top wavelength more than 500 nm.

The display panel DP may be disposed under the cover member 50. The display panel DP may include a protection film 92 and an adhesive member 94 disposed under the substrate 10. According to an embodiment, the protection film 92 may include a protection film base 92a and an adhesive layer 92b. The protection film base 92a may include polyethylene terephthalate (PET) or polyimide (PI). In addition, the adhesive layer 92b may include various adhesive substances. The adhesive layer 92b may be disposed on the entire surface of the substrate 10, and an opening 920P may be formed by removing a part of the protection film base 92a which is disposed on the adhesive layer 92b. According to an embodiment, although not shown in the drawings, the opening 920P may also be formed by removing a part of the protection film base 92a and a part of the adhesive layer 92b. In this case, both the protection film base 92a and the adhesive layer 92b may not be present at the opening 920P.

The display panel DP may include a cushion layer 91 disposed between the protection film bases 92a. The cushion layer 91 may be disposed in an area where the first area 1A and the second area 2A face each other. That is, the cushion layer 91 may be disposed between a first area 1A of the protection film base 92a and a second area 2A of the protection film base 92a. After the substrate 10 is bent, the cushion layer 91 may be placed in a space where the first area 1A is separated from the second area 2A to support the display panel DP and absorb impact. The cushion layer 91 may include an elastic material. However, the display device is not limited thereto, and it is also possible for the cushion layer 91 to be attached to the protection film base 92a before bending.

In the case as described above, the adhesive member 94 may be disposed between the second protective layer 93b and the second area 2A of the protection film base 92a to secure the second protective layer 93b to the protection film base 92a.

The display panel DP may be connected to the display circuit board 51 via an anisotropic conductive film.

A touch sensor driver 53 may be disposed on the display circuit board 51. According to an embodiment, although not shown in the drawings, a display driver 52 may be directly disposed on the substrate 10 of the display panel DP. The display driver 52 may also be disposed on the display circuit board 51. Hereinafter, a case where the display driver 52 is disposed on the display circuit board 51 will be described in detail for the convenience of description.

At least a part of the substrate 10 of the display panel DP as described above may be bent. According to an embodiment, the bending protection layer BPL may be disposed on the bent portion of the substrate 10 to prevent cracks or other damage of the substrate 10. The bending protection layer BPL may include a polymer resin such as polyethyleneterephthalate (PET) or polyimide (PI).

According to an embodiment, the display device 1 may include a panel protection member (not shown) disposed under the display panel DP.

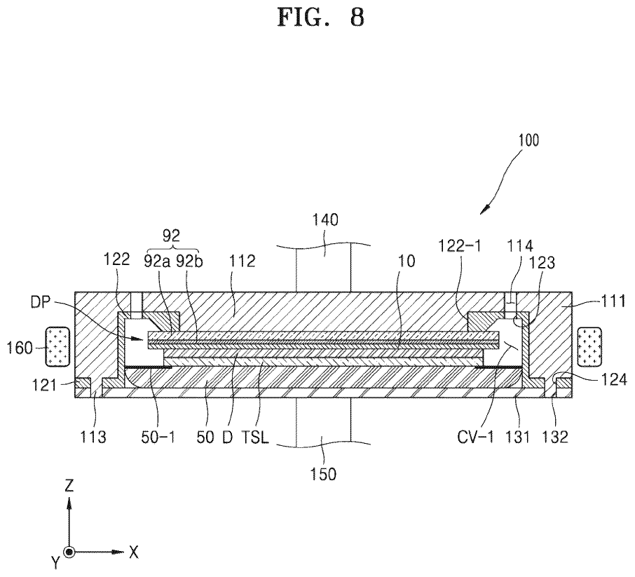

The touch sensor layer TSL may be formed in the form of a panel or a film. For example, the touch sensor layer TSL may be integrated with the display panel DP. For example, in the case of the touch sensor layer TSL being formed in the form of a film, the touch sensor layer TSL may be integrated with a thin-film encapsulation layer which encapsulates the display panel DP (See FIG. 8).

The touch sensor layer TSL may include a plurality of electrodes disposed on the display panel DP. In this case, the plurality of electrodes may be disposed on the thin-film encapsulation (TFE) layer to cross each other, and a change in electrostatic capacity that varies according to a touch of the user may be measured at intersections of the plurality of electrodes. The touch sensor layer TSL as described above may be connected to the display circuit board 51.

The touch sensor driver 53 may apply touch driving signals to the touch sensor layer TSL, receive first sensing signals detected by the touch sensor layer TSL, and determine a touch location of the user by analyzing the first sensing signals. In addition, the touch sensor driver 53 may apply touch driving signals to a sensor device (not shown), receive second sensing signals detected by the sensor device, and determine a touch location of a signal input unit (not shown) by analyzing the second sensing signals.

According to an embodiment, a functional layer (not shown) may be disposed on the touch sensor layer TSL. The functional layer may include an anti-reflection layer. The anti-reflection layer may reduce the reflectance of light (external light) incident from the outside.

The anti-reflection layer may include a polarizing film. The polarizing film may include a phase retardation film such as a linear polarizing plate and a quarter-wave (λ/4) plate. The phase retardation film may be disposed on the touch sensor layer, and the linear polarizing plate may be disposed on the phase retardation film.

According to an embodiment, the anti-reflection layer may include a filter layer including a black matrix and color filters. The color filters may be arranged in consideration of colors of light emitted from each of the sub-pixels of the display panel DP. For example, the color filters may include a red, green, or blue color filter. The color filters may be disposed on the touch sensor layer TSL of the display panel DP without using a separate adhesive layer.

According to an embodiment, the anti-reflection layer may include a destructive interference structure. The destructive interference structure may include a first reflection layer and a second reflection layer arranged on different layers. The first reflected light from the first reflective layer and the second reflected light from the second reflective layer may undergo destructive interference, thereby reducing reflectance of external light.

The functional layer may further include an impact absorbing layer. The impact absorbing layer may serve to protect underlying structures, such as the display panel, from an external impact. The impact absorbing layer may be a polymer film and may include, for example, at least one of polyethylene terephthalate (PET), polyethylene naphthalate (PEN), polyether sulfone (PES), polyimide (PI), polyarylate (PAR), polycarbonate (PC), polymethyl methacrylate (PMMA), or cycloolefin copolymer (COC) resin.

According to an embodiment, the functional layer may include the anti-reflection layer and the impact absorbing layer. In this case, the anti-reflection layer and the impact absorbing layer may be sequentially stacked on the display panel DP or the touch sensor layer TSL.

The display circuit board 51 may be attached onto one side of the display panel DP. Specifically, the display circuit board 51 may be connected to pads which is formed on one side of the display panel DP by using an anisotropic conductive film.

The display circuit board 51 may be bent from the top to the bottom of the display panel DP. The display circuit board 51 may be connected to the main circuit board 70 via a display connector (not shown).

The bracket 60 may be disposed under the display panel DP to support the display panel DP. The bracket 60 may include plastic, metal, or both plastic and metal. According to an embodiment, the bracket 60 may have a connector hole 61 through which the connector passes. In addition, the bracket 60 may have a camera hole 62 into which a camera device 73 is inserted.

The bracket 60 may have an accommodation space 64 to accommodate a protective layer 93. In addition, the bracket 60 may have a support 63 protruding toward the display panel DP to support the rear surface of the display panel DP. In this case, the support 63 may be in close contact with the rear surface of the display panel DP.

The main circuit board 70 as described above may be provided separately from the display circuit board 51 or integrated therewith. If the main circuit board 70 is separated from the display circuit board 51 to be distinguished from each other, the main circuit board 70 may be connected to the display circuit board 51 using a cable or the like.

The main circuit board 70 may include a main processor 71, a camera device 73, a main connector 75, and other components (not shown). The main processor 71 may be formed as an integrated circuit. The camera device 73 may be disposed on both the upper surface and the lower surface of the main circuit board 70, and each of the main processor 71 and the main connector 75 may be disposed on either the upper surface or the lower surface of the main circuit board 70.

The main processor 71 may control all functions of the display device 1. For example, the main processor 71 may output digital video data to the display driver 52 via the display circuit board 51 to display an image through the display panel DP. In addition, the main processor 71 may receive sensing data from the touch sensor driver 53. The main processor 71 may determine whether the user touches the tough sensor layer TSL or not based on the sensing data and execute an operation corresponding to either a direct touch or a proximity touch of the user. For example, the main processor 71 may calculate coordinates of a user's touch by analyzing sensing data, and execute an application or perform an operation indicated by an icon touched by the user. The main processor 71 may be an application processor, a central processing unit, or a system chip made of an integrated circuit.

The camera device 73 may process image frames such as still images or moving images obtained by an image sensor in a camera mode and output the results to the main processor 71. The camera device 73 may include at least one of a camera sensor (e.g., charge coupled device (CCD) and complementary metal oxide semiconductor (CMOS)), a photo sensor (or image sensor), or a laser sensor. The camera device 73 may be connected to an image sensor and process an image input through the image sensor.

The cable passing through the cable hole 61 may be connected to the main connector 75, and thus the main circuit board 70 may be electrically connected to the display circuit board 51.

The main circuit board 70 may further include at least one wireless communicator, at least one input unit, at least one sensor device, at least one output unit, at least one interface device, a memory, and a power supply device in addition to the main processor 71, the camera device 73, and the main connector 75.

The wireless communicator may include at least one of a broadcast receiving module, a mobile communication module, a wireless Internet module, a short-range communication module, or a location information module.

The broadcast receiving module may receive broadcast signals or broadcast-related information from an external broadcast control server via a broadcast channel. The broadcast channel may include satellite channels or terrestrial channels.

The mobile communication module may transmit and receive wireless signals to and from at least one of a base station, an external terminal, or a server on a mobile communication network constructed according to technical standards or communication methods for mobile communication (e.g., Global System for Mobile Communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), and Long Term Evolution-Advanced (LTE-A)). The wireless signals may include various forms of data according to transmission and reception of voice call signals, video call signals, or text/multimedia message.

The wireless Internet module may refer to a module for wireless Internet access. The wireless Internet module may be configured to transmit and receive wireless signals in a communication network according to wireless Internet technologies. The wireless Internet technologies may be, for example, Wireless LAN (WLAN), Wireless-Fidelity (Wi-Fi), Wireless Fidelity (Wi-Fi) Direct, and Digital Living Network Alliance (DLNA).

Short-range communication modules are for short-range communication, and the short-range communication may be supported by using at least one of the technologies including Bluetooth™, Radio Frequency Identification (RFID), Infrared Data Association (IrDA), Ultra Wideband (UWB), ZigBee, Near Field Communication (NFC), Wireless-Fidelity (Wi-Fi), Wi-Fi Direct, and Wireless Universal Serial Bus (Wireless USB). The short-range communication module may support wireless communication between the display device 1 and a wireless communication system, between the display device 1 and a different electronic device, or between the display device 1 and a network at which a different electronic device is located (or external server) via short-range wireless area networks. The short-range wireless communication network may be a short-range wireless personal area network. The different electronic device may be a wearable device configured to exchange data (or operate in linkage) with the display device 1.

The location information module is a module for obtaining a location (or current location) of the display device 1, and examples thereof may be a Global Positioning System (GPS) module or a Wireless Fidelity (Wi-Fi) module. For example, the display device 1 may obtain a location of the display device 1 by using a signal received from a GPS satellite in the case of utilizing a GPS module. In addition, the display device 1 may obtain a location of the display device 1 based on information of a wireless access point (AP) transmitting or receiving a wireless signal to or from a Wi-Fi module in the case of utilizing the Wi-Fi module. The location information module is a module used to obtain a location (or current location) of the display device 1. The location information module is not limited to a module that directly calculates or acquires the location of the display device 1.

The input unit may include an image input unit configured to input an image signal such as the camera device, an audio input unit configured to input an audio signal such as a microphone, or an input device configured to receive information from a user.

The camera device 73 processes image frames such as still images or moving images obtained by the image sensor in a video call mode or a camera shooting mode. The processed image frames are displayed on the display panel DP or stored in a memory.

The microphone processes external audio signals into electrical voice data. The processed voice data may be used in various methods according to functions performed in the display device 1 or applications being executed. Various noise removal algorithms may be implemented in the microphone to remove noise generated during a process of receiving external audio signals.

The main processor 71 may control the operation of the display device 1 to correspond to information input via the input device. The input device may include a mechanical input device such as a button, a dome switch, a jog wheel, or a jog switch located at the rear surface or the side surface, or a touch input device. The touch input device may be formed as a touch sensor layer TSL of the display panel DP.

The sensor device may include at least one sensor configured to detect at least one of information in the display device 1, information about an environment surrounding the display device 1, and user information, and may generate a sensing signal corresponding thereto. The main processor may control driving or operation of the display device 1, or perform data processing, functions, or operations related to applications installed on the display device 1 based on the sensing signal. The sensor device may include at least one of a proximity sensor, an illumination sensor, an acceleration sensor, a magnetic sensor, a G-sensor, a gyroscope sensor, a motion sensor, an RGB sensor, an infrared (IR) sensor, a finger scan sensor, an ultrasonic sensor, an optical sensor, a battery gauge, an environmental sensor (e.g., barometer, hygrometer, thermometer, radiation detection sensor, heat detection sensor, and gas detection sensor), and a chemical sensor (e.g., electronic nose, healthcare sensor, and biometric sensor).

The proximity sensor refers to a sensor that detects the presence of an object approaching a detection surface or a nearby object by use of electromagnetic field intensity or infrared ray without physical contact. Examples of the proximity sensor may include a through-beam photoelectric sensor, a direct reflective photoelectric sensor, a mirror reflective photoelectric sensor, a high frequency oscillation proximity sensor, a capacitance proximity sensor, a magnetic proximity sensor, or an infrared proximity sensor. The proximity sensor may detect not only a proximity touch, but also a proximity touch pattern such as a proximity touch distance, a proximity touch direction, a proximity touch speed, a proximity touch time, a proximity touch location, and a state of a proximity touch motion. The main processor may process data (or information) corresponding to proximity touch operation and a proximity touch pattern detected by the proximity sensor, and control the display panel DP to display visual information corresponding to the processed data.

The ultrasonic sensor may recognize location information of an object by using ultrasonic waves. The main processor may calculate a location of an object using information detected by an optical sensor and a plurality of ultrasonic sensors. Because the velocity of light is different from the velocity of the ultrasonic waves, a location of an object may be calculated by using time taken for light to reach the optical sensor and time taken for ultrasonic waves to reach the ultrasonic sensor.

The output unit is configured to generate outputs related to visual, auditory, or tactile sensations, and may include at least one of an audio output unit, a haptic module, an optical output unit.

The audio output unit may output audio data received from the wireless communicator or stored in the memory in a call signal reception mode, a call mode or recording mode, a voice recognition mode, or a broadcast reception mode. The audio output unit may output audio signals related to functions (e.g., call signal reception sound and message reception sound) performed in the display device 1. The audio output unit may include a receiver and a speaker. At least one of the receiver and the speaker may be a sound generating device attached to the bottom of the display panel DP to vibrate the display panel DP, thereby outputting sounds. The sound generating device may be a piezoelectric element or piezoelectric actuator that contracts and expands in accordance with an electrical signal or an exciter that vibrates the display panel DP by creating a magnetic force by using a voice coil.

The haptic module generates various tactile effects that the user may feel. The haptic module may provide the user with vibration as a tactile effect. The intensity, pattern, and the like of vibration generated by the haptic module may be controlled by a user's selection or the settings of the main processor. For example, the haptic module may output different vibrations in a synthesized state or sequentially. The haptic module may generate, in addition to the vibrations, various other tactile effects such as stimulative effects caused by the arrangement of pins movable perpendicularly to the skin in contact herewith, injection force or suction force of air through an injection port or a suction port, rubbing against the skin, contact with an electrode, and electrostatic force, and effects of reproducing hot and cold sensations using elements absorbing or releasing heat. The haptic module may be configured not only to transmit tactile effects through direct contact, but also to allow a user to feel tactile effects through sensation of muscles, such as fingers or arms.

The optical output unit outputs a signal to notify occurrence of events by using light of a light source. Examples of events generated in the display device 1 may include message reception, call signal reception, missed call, alarm, schedule reminder, email reception, or information reception via applications. The signal output from the optical output unit may be implemented as the display device 1 emits light of a single color or multiple colors from the front surface or the rear surface. The output of the signal may be terminated as the display device 1 detects that the user has confirmed the event.

The interface device serves as a path to various types of external devices connected to the display device 1. The interface device may include at least one of a wired/wireless headset port, an external charger port, a wired/wireless data port, a memory card port, a port for connection with a device having an identification module, an audio input/output (I/O) port, a video I/O port, or an earphone port. The display device 1 may perform appropriate control related to a connected external device in response to connection of the external device to the interface device.

The memory stores data supporting various functions of the display device 1. The memory may store various application programs run on the display device 1 and data and instructions for the operation of the display device 1. At least some of the plurality of applications may be downloaded from an external server via wireless communication. The memory may store applications for the operation of the main processor and may also temporarily store input/output data, such as, phonebooks, messages, still images, and moving images. In addition, the memory may store haptic data for vibration of various patterns provided to the haptic module and audio data about various sounds provided to the audio output unit. The memory may include at least one storage medium of a flash memory type memory, a hard disk type memory, a Solid State Disk (SSD) type memory, a Silicon Disk Drive (SDD) type memory, a multimedia card micro type memory, a card type memory (e.g., SD or XD memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disc.

The power supply device may supply power to respective components included in the display device 1 upon receiving external power or internal power under the control of the main processor. The power supply device may include a battery. In addition, the power supply device may include a connection port, and the connection port may be configured as an example of the interface device to which an external charger that supplies power for charging the battery is electrically connected. The power supply device may be configured to charge the battery wirelessly without using the connection port. The battery may receive power from an external wireless power transmission device by using an inductive coupling method based on the magnetic induction phenomenon or a magnetic resonance coupling method based on the electromagnetic resonance phenomenon. The battery may be disposed not to overlap the main circuit board in a third direction (Z direction). The battery may overlap a battery hole of the bracket 60.

The lower cover 90 may be disposed under the main circuit board 70 and the battery. The lower cover 90 may be coupled to the bracket 60 to be fixed thereto. The lower cover 90 may define an exterior appearance of the lower surface of the display device 1. The lower cover 90 may include plastic, metal, or both plastic and metal.

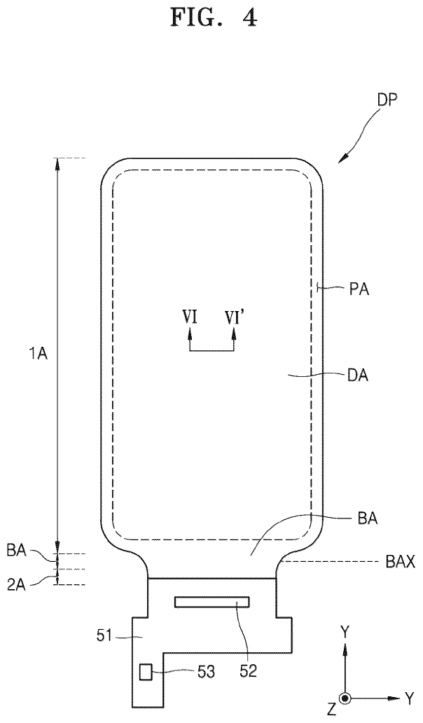

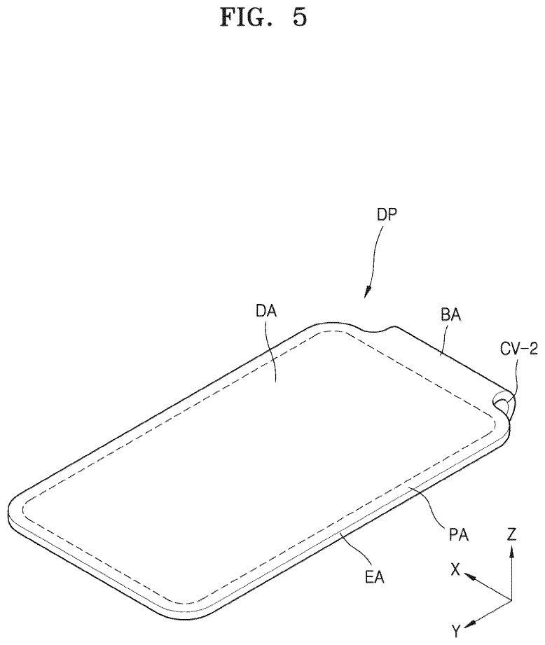

FIG. 4 is a schematic plan view of the display panel illustrated in FIG. 2. FIG. 5 is a schematic perspective view illustrating a portion of the display panel, shown in FIG. 4, is in a bending state.

Referring to FIGS. 4 and 5, the display panel DP may be a light emitting display panel including a light emitting element. For example, the display panel DP may be an organic light emitting display panel using an organic light emitting diode including an organic emission layer, a micro light emitting diode display panel using a micro light emitting diode (micro LED), a quantum dot light emitting display panel using a quantum dot light emitting diode including a quantum dot emission layer, or an inorganic light emitting display panel using an inorganic light emitting element including an inorganic semiconductor.

The display panel DP may be a flexible display panel which is easily bendable, foldable, or rollable. For example, the display panel DP may be a foldable display panel that may be folded and unfolded, a curved display panel with a curved display surface, a bended display panel with an area, other than the display surface, being bent, a rollable display panel that may be rolled or unrolled, and a stretchable display panel that may be elongated.

The display panel DP may be a transparent display panel through which an object or background disposed below the lower surface of the display panel DP is visible. The display panel DP may be a reflective display panel that may reflect an object or background above the upper surface of the display panel DP.

The display panel DP as described above may include a display area DA in which an image is displayed, and a peripheral area PA surrounding the display area DA. In the peripheral area PA, a separate driving circuit, pad, and the like may be disposed.

The display panel DP may include a first area 1A disposed in the display area DA, a bending area BA that is bendable with respect to a bending axis BAX, and a second area 2A connected to the bending area BA and connected to the display circuit board 51. The second area 2A and the bending area BA may be included in the peripheral area PA, and an image may not be displayed therefrom. In the display panel DP, a part of the substrate 10 may be bent with respect to an imaginary bending axis BAX disposed in the bending area BA. In this case, the first area 1A, the second area 2A, and the bending area BA may form a ‘U’ shape, creating a second space CV-2 in which a second protective layer (for example, 93b in FIGS. 3A and 3B above) can be placed. As depicted in FIGS. 3A and 3B above, a first protective layer 93a may be disposed on the edge EA of the display panel DP and the outer surface of the bending area BA, while the second protective layer 93b may be disposed inside the first space CV-1 (refer to FIG. 8 below).

The display circuit board 51 may be attached to one side of the display panel DP, e.g., a lower side of the display panel DP. One side of the display circuit board 51 may be attached to the lower side of the display panel DP by using an anisotropic conductive film.

The display driver 52 may be disposed on the display circuit board 51. The display driver 52 may receive control signals and power voltages and generate and output signals and voltages for driving the display panel DP. The display driver 52 may be formed as an integrated circuit (IC).

The display circuit board 51 may be attached to the display panel DP. For example, the display circuit board 51 and the display panel DP may be attached to each other by using the anisotropic conductive film. The display circuit board 51 may be a flexible printed circuit board (FPCB) that is bendable, or a composite printed circuit board including both a rigid printed circuit board (PCB) that is hard and not easily bendable and a FPCB.

The touch sensor driver 53 may be disposed on the display circuit board 51. The touch sensor driver 53 may be formed as an integrated circuit. The touch sensor driver 53 may be attached onto the display circuit board 51. The touch sensor driver 53 may be electrically connected to touch electrodes of the touch sensor layer of the display panel DP via the display circuit board 51.

The touch sensor layer of the display panel DP may detect a touch input of the user by using at least one of various touch methods such as a resistive film method and a capacitive method. For example, in the case where the touch sensor layer of the display panel DP detects a touch input of the user by a capacitive method, the touch sensor driver 53 may determine a user's touch by applying driving signals to driving electrodes among touch electrodes, and detecting voltages charged in mutual capacitance (hereinafter, referred to as “mutual capacity”) between the driving electrodes and sensing electrodes via the sensing electrodes among the touch electrodes. The user's touch may include a contact touch and a proximity touch. The contact touch indicates that an object such as a finger of the user or a pen directly contacts the cover member disposed on the touch sensor layer. The proximity touch indicates that an object such as a finger of the user or a pen is located close to, but not in contact with, the cover member, such as hovering. The touch sensor driver 53 may transmit sensor data to the main processor based on the detected voltages, and the main processor calculates touch coordinates where the touch input occurred by analyzing the sensor data.

The power supply device may further be disposed on the display circuit board 51 to supply driving voltages which drive pixels of the display panel DP, a scan drive unit, and the display driver 52. The power supply device may be integrated with the display driver 52, and in this case, the display driver 52 and the power supply device may be formed as a single integrated circuit.

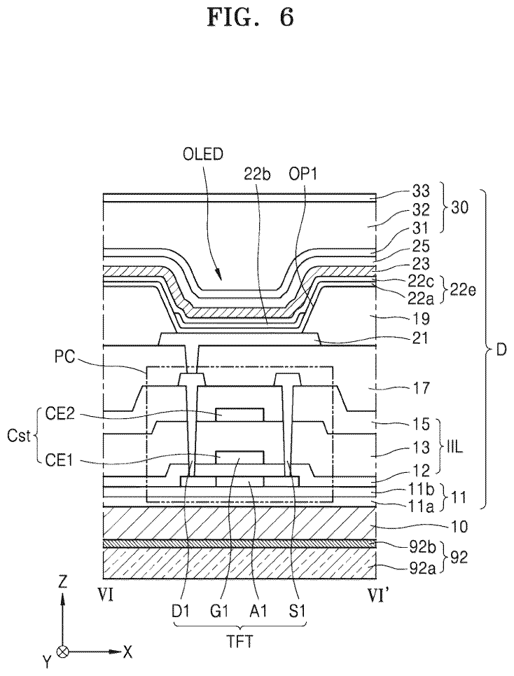

FIG. 6 is a cross-sectional view taken along a line VI-VI′ of FIG. 4.

Referring to FIG. 6, the display panel DP may include a substrate 10 and a display layer D. The display layer D may include a buffer layer 11, a circuit layer (not shown), a display element layer OLED, and a thin-film encapsulation layer 30.

As described above, the substrate 10 may be formed of an insulating material such as glass, quartz, or a polymer resin. The substrate 10 may be a flexible substrate that is bendable, foldable, or rollable.

The buffer layer 11 may be disposed on the substrate 10 to reduce or block penetration of foreign substances, moisture, or external air from areas below the substrate 10 and may provide a flat surface on the substrate 10. The buffer layer 11 may include an inorganic material such as an oxide or a nitride, an organic material, or an organic-inorganic composite, and may have a single-layer or multi-layer structure of an inorganic material and an organic material. A barrier layer (not shown) blocking penetration of external air may further be included between the substrate 10 and the buffer layer 11. According to an embodiment, the buffer layer 11 may include a silicon oxide (SiO₂) or silicon nitride (SiN_{X}). The buffer layer 11 may include a first buffer layer 11a and a second buffer layer 11b disposed on the first buffer layer 11a.

The circuit layer may be disposed on the buffer layer 11 and may include a pixel circuit PC, a first gate insulating layer 12, a second gate insulating layer 13, an interlayer insulating layer 15, and a planarization layer 17. The pixel circuit PC may include a thin film transistor TFT and a storage capacitor Cst.

The thin film transistor TFT may be disposed on the buffer layer 11. The thin film transistor TFT includes a first semiconductor layer A1, a first gate electrode G1, a first source electrode S1, and a first drain electrode D1. The thin film transistor TFT may be connected to a pixel electrode 21 to drive the organic light emitting diode OLED.

The first semiconductor layer A1 may be disposed on the buffer layer 11 and may include polysilicon or amorphous silicon. The first semiconductor layer A1 may include an oxide of at least one selected from indium (In), gallium (Ga), stannum (Sn), zirconium (Zr), vanadium (V), hafnium (Hf), cadmium (Cd), germanium (Ge), chromium (Cr), titanium (Ti), and zinc (Zn). The first semiconductor layer A1 may include a channel region and a source region and a drain region doped with impurities.

A first gate insulating layer 12 may be disposed on the first semiconductor layer A1. The first gate insulating layer 12 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The first gate insulating layer 12 may be a single layer or multilayers including the above-described inorganic insulating material.

The first gate electrode G1 may be disposed on the first gate insulating layer 12 and overlap a portion of the first semiconductor layer A1. The first gate electrode G1 may include molybdenum (Mo), aluminum (Al), copper (Cu), titanium (Ti), or the like, and have a single layer or multilayers. For example, the first gate electrode G1 may be a single layer including Mo.

The second gate insulating layer 13 may be disposed on the first gate electrode G1. The second gate insulating layer 13 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The second gate insulating layer 13 may be a single layer or multilayers including the above-described inorganic insulating materials.

A first upper electrode CE2 of a storage capacitor Cst may be disposed on the second gate insulating layer 13.

The first upper electrode CE2 may overlap the first gate electrode G1 thereunder in the display area DA. The first gate electrode G1 and the first upper electrode CE2 overlapping each other with the second gate insulating layer 13 therebetween may form the storage capacitor Cst. The first gate electrode G1 may also serve as a first lower electrode CE1 of the storage capacitor Cst.

The first upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may be a single layer or multilayers of the above-described materials.

The interlayer insulating layer 15 may be disposed on the first upper electrode CE2. The interlayer insulating layer 15 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like. The interlayer insulating layer 15 may be a single layer or multilayers including the above-described materials.

The first source electrode S1 and the first drain electrode D1 may be disposed on the interlayer insulating layer 15. The first source electrode Si and the first drain electrode D1 may include a conductive material including molybdenum (Mo), aluminum (Al), copper (Cu), titanium (Ti), or the like, and may be formed as a single layer or multilayers including the materials. For example, the first source electrode S1 and the first drain electrode D1 may have a multilayer structure including Ti/Al/Ti.

The planarization layer 17 may be disposed on the first source electrode Si and the first drain electrode D1. The planarization layer 17 may have a flat upper surface so that a pixel electrode 21 disposed thereon is formed flat.

The planarization layer 17 may include an organic material or an inorganic material, and may have a single-layer or multi-layer structure. The planarization layer 17 may include a general-purpose polymer such as benzocyclobutene (BCB), polyimide, hexamethyldisiloxane (HMDSO), polymethylmethacrylate (PMMA), or polystyrene, a polymer derivative having a phenol-based group, an acrylic polymer, an imide polymer, an aryl ether polymer, an amide polymer, a fluorine polymer, a p-xylene polymer, or a vinyl alcohol polymer. The planarization layer 17 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). When forming the planarization layer 17, chemical, mechanical polishing may be performed on the upper surface of the planarization layer 17 to provide a flat upper surface.

The planarization layer 17 may have a via hole extending to one of the first source electrode S1 and the first drain electrode D1 of the thin film transistor TFT, and the pixel electrode 21 may contact the first source electrode S1 or the first drain electrode D1 through the via hole to be electrically connected to the thin film transistor TFT.

The pixel electrode 21 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 21 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the pixel electrode 21 may have a structure having films formed of ITO, IZO, ZnO, or In₂O₃ on top/bottom of the above-described reflective film. In this case, the pixel electrode 21 may have a multilayer structure including ITO/Ag/ITO.

A pixel definition film 19 may cover an edge of the pixel electrode 21 on the planarization layer 17 and may have a first opening OP2 extending to the center of the pixel electrode 21. Size and shape of a light emitting area, i.e., sub-pixel Pm, of an organic light emitting diode OLED may be defined by the first opening OP1.

The pixel definition film 19 may increase a distance between the edge of the pixel electrode 21 and a counter electrode 23, which is disposed on the pixel electrode 21, and serve to prevent arc, or the like from occurring on the edge of the pixel electrode 21. The pixel definition film 19 may include an organic insulating material such as polyimide, polyamide, an acrylic resin, benzocyclobutene, hexamethyldisiloxane (HMDSO) or a phenol resin, which is deposited on the planarization layer 17 through a method such as spin coating.

An emission layer 22b formed to correspond to each pixel electrode 21 is disposed in the first opening OP1 of the pixel definition film 19. The emission layer 22b may include a polymer material or a low-molecular weight material, and may emit red, green, blue or white light.

An organic functional layer 22e may be disposed on or under the emission layer 22b. The organic functional layer 22e may include a first functional layer 22a or a second functional layer 22c. The first functional layer 22a or the second functional layer 22c may be omitted.

The first functional layer 22a may be disposed under the emission layer 22b. The first functional layer 22a may be a single layer or multilayers including an organic material. The first functional layer 22a may be a hole transport layer HTL as a single-layer structure. The first functional layer 22a may include a hole injection layer HIL and a hole transport layer HTL. The first functional layer 22a may be integrally formed to correspond to organic light emitting diodes OLED.

The second functional layer 22c may be disposed on the emission layer 22b. The second functional layer 22c may be a single layer or multilayers including an organic material. The second functional layer 22c may include an electron transport layer (ETL) or an electron injection layer (EIL). The second functional layer 22c may be integrally formed to correspond to organic light emitting diodes OLED included in the display area DA.

The counter electrode 23 is disposed on the second functional layer 22c. The counter electrode 23 may include a conductive material with a low work function. For example, the counter electrode 23 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. The counter electrode 23 may further include a layer such as ITO, IZO, ZnO or In₂O₃ on the (semi-)transparent layer including the above-described materials. The counter electrode 23 may be integrally formed to correspond to organic light emitting diodes OLED included in the display area DA.

The layers from the pixel electrode 21 to the counter electrode 23 formed in the display area DA may constitute the organic light emitting diode OLED.

An upper layer 25 including an organic material may be formed on the counter electrode 23. The upper layer 25 may be a layer for protecting the counter electrode 23 as well as increasing light extraction efficiency. The upper layer 25 may include an organic material with higher refractive index than that of the counter electrode 23. The upper layer 25 may include multilayers having different refractive indices. For example, the upper layer 25 may be provided by stacking a first high refractive index layer, a low refractive index layer and a second high refractive index layer in turn. In this case, the refractive index of the high refractive index layer may be 1.7 or more, and the refractive index of the low refractive index layer may be 1.3 or less.

The upper layer 25 may further include LiF. The upper layer 25 may further include an inorganic material such as silicon oxide (SiO₂) or silicon nitride (SiNx). The upper layer 25 may be omitted.

The display device DP according to an embodiment may include a thin-film encapsulation layer 30 disposed on the upper layer 25 to shield the upper layer 25.

The thin-film encapsulation layer 30 may be disposed on the upper layer 25 and be in direct contact with the upper layer 25. In this case, the thin-film encapsulation layer 30 may partially cover the display area DA and the peripheral area NDA to prevent penetration of external moisture and oxygen. The thin-film encapsulation layer 30 may include at least one organic encapsulation layer and at least one inorganic encapsulation layer. Hereinafter, a thin-film encapsulation layer 30 including a first inorganic encapsulation layer 31, an organic encapsulation layer 32, and a second inorganic encapsulation layer 33 sequentially stacked on the upper surface of the upper layer 25 will be described in detail for the convenience of description.

The first inorganic encapsulation layer 31 may cover the counter electrode 23 and may include silicon oxide, silicon nitride, or silicon oxynitride. Because the first inorganic encapsulation layer 31 is formed in accordance with the underlying structure, the upper surface of the first inorganic encapsulation layer 31 may not be flat. Unlike the first inorganic encapsulation layer 31, the upper surface of the organic encapsulation layer 32 covering the first inorganic encapsulation layer 31 may become flat. Specifically, the organic encapsulation layer 32 may be provided to have an approximately flat upper surface in a region corresponding to the display area DA. The organic encapsulation layer 32 may include at least one material selected from the group consisting of polyethylene terephthalate, polyethylene naphthalate, polycarbonate, polyimide, polyethylene sulfonate, polyoxymethylene, polyarylate, and hexamethyldisiloxane. The second inorganic encapsulation layer 33 may cover the organic encapsulation layer 32 and may include silicon oxide, silicon nitride, or silicon oxynitride.

The touch sensor layer TSL may be disposed on the above-described thin-film encapsulation layer 30.

The protection film 92 including the protection film base 92a and the adhesive layer 92b may be disposed under the substrate 10 described above.

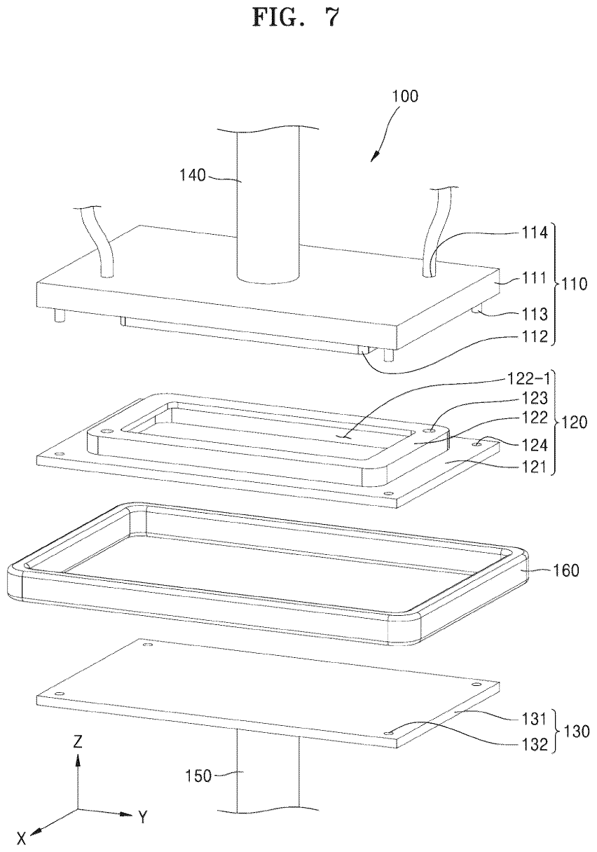

FIG. 7 is a schematic perspective view of a manufacturing apparatus for a display device according to an embodiment. FIG. 8 is a schematic cross-sectional view of the manufacturing apparatus for the display device illustrated in FIG. 7.

Referring to FIGS. 7 and 8, a manufacturing apparatus 100 for a display device may include a first jig 110, a mold 120, a second jig 130, a drive unit (not shown), and a light source 160.

The first jig 110 may include a first jig body 111, a pressurization portion 112, a coupling portion 113, and a first injection portion 114. The pressurization portion 112 may protrude from the first jig body 111. The pressurization portion 112 may be in contact with a part of the display panel DP to apply a force to the part of the display panel DP. The coupling portion 113 may protrude from the first jig body 111. In this case, the coupling portion 113 may be formed in a pin shape to protrude from the first jig body 111. In this case, the coupling portion 113 may be provided in plural, and the plurality of coupling portions 113 may be disposed at each corners of the first jig body 111. The first injection portion 114 may be arranged in the first jig body 111. In this case, at least one first injection portion 114 may be provided, and if a plurality of first injection portions 114 are provided, the plurality of first injection portions 114 may be disposed to be spaced apart from each other. The first injection portion 114 may be connected to a separate supply pipe which supplies the composition according to the present disclosure from the outside, or a nozzle spraying the composition according to the present disclosure may be inserted to the first injection portion 114.

The mold 120 may move together with the first jig 110 or be coupled to the first jig 110. The mold 120 may include a mold body 121, a protruding portion 122, a second injection portion 123, and a first receiving portion 124. The mold body 121 may be in the form of a plate and may be close to the second jig 130 to selectively contact the second jig 130. The protruding portion 122 may protrude toward the first jig 110 from the mold body 121. The protruding portion 122 may have an opening region 122-1 and the opening region 122-1 may accommodate the insertion of the pressurization portion 112. In this case, the pressurization portion 112 may pass through the opening region 122-1 and make contact with the display panel DP. The second injection portion 123 may be arranged to correspond to the first injection portion 114. The second injection portion 123 may be arranged in the protruding portion 122. The first receiving portion 124 may be arranged to correspond to the coupling portion 113 and may include at least one hole.

The second jig 130 may include a second jig body 131 in a plate shape and a second receiving portion 132 into which the coupling portion 113 is inserted. The second receiving portion 132 may be arranged in the second jig body 131 to correspond to the coupling portion 113 and the first receiving portion 124. In this case, the second receiving portion 132 may accommodate a part of the coupling portion 113, which passes through the first receiving portion 124.

The drive unit may be connected to at least one of the first jig 110 and the second jig 130 to enable a linear movement of at least one of the first jig 110 and the second jig 130. For example, the drive unit may be connected to the first jig 110 and move the first jig 110 close to the second jig 130 or away from the second jig 130. For example, the drive unit may be connected to the second jig 130 and move the second jig 130 close to the first jig 110 or away from the first jig 110. For example, the drive unit may include a first drive unit 140 connected to the first jig 110 and a second drive unit 150 connected to the second jig 130. Hereinafter, a case where the drive unit includes the first drive unit 140 and the second drive unit 150 will be described in detail for the convenience of description.

The drive unit as described above may be formed in various shapes. For example, the drive unit may include a cylinder. For example, the drive unit may also include a linear motor. For example, the drive unit may include a motor and a ball screw connected to the motor. However, the drive unit is not limited to that described above and may include any device or any structure connected to at least one of the first jig 110 and the second jig 130 to move the at least one of the first jig 110 and the second jig 130.

The light source 160 may be arranged on a side of the display panel DP and emit light toward the display panel DP. In this case, the light source 160 may emit visible light to the outside, and particularly, the light source 160 may supply light with a peak top wavelength in a range from about 450 nm to about 500 nm. The light source 160 may have various shapes. For example, the light source 160 may be in the form of a point light source. For example, the light source 160 may be arranged on a side of the display panel DP and formed in a linear shape. The light source 160 may be arranged to surround the entire side of the display panel DP.

Hereinafter, the operation of the manufacturing apparatus for the display device 100 will be described in detail. After placing the display panel DP on the second jig 130, the first jig 110 and the mold 120 may be disposed on the display panel DP. At this time, at least one of the first drive unit 140 and the second drive unit 150 may position the first jig 110 and the second jig 130 to be spaced apart from each other. In addition, the mold 120 may be in a state coupled with the first jig 110, or only the mold 120 may be positioned on the display panel DP. In this case, the mold 120 and the second jig 130 may be disposed such that the first receiving portion 124 and the second receiving portion 132 may be arranged to correspond to each other.

Upon operation of the at least one of the first drive unit 140 and the second drive unit 150, the first jig 110 and the second jig 130 are located close to each other. In this case, the first jig 110 is in close contact with the second jig 130. The protruding portion 122 is inserted into the opening region 122-1 and make contact with the display panel DP. By applying a force to the display panel DP, the movement of the display panel DP may be prevented. In addition, the coupling portion 113 may be inserted into the first receiving portion 124 and the second receiving portion 132, which prevents the mold 120 from moving and also prevents relative movement of the first jig 110 and the second jig 130.

Upon completion of the above-described processes, the mold 120, the second jig 130, and the display panel DP may form a first space CV-1. A photocurable resin may be injected into the first space CV-1 through the first injection portion 114 and the second injection portion 123, which are connecting to the first space CV-1. Subsequently, a resin may be cured by light emitted from the light source 160 toward the entire side of the first jig 110 and the mold 120. In this case, the first jig 110 and the mold 120 may be formed of a transparent material, respectively. For example, the first jig 110 may include at least one of transparent materials such as polymethyl methacrylate (PMMA), polycarbonate (PC), glass, and quartz. In addition, the mold 120 may include at least one of elastic and transparent materials such as silicon rubber, plastic rubber, and Teflon rubber.

Upon completion of curing the resin by emitted light, the first jig 110 may be separated from the second jig 130 by driving at least one of the first drive unit 140 and the second drive unit 150. In this case, the mold 120 may move together along with the first jig 110 to be separated from the second jig 130, or it is also possible to separate the first jig 110 from the mold 120 and then remove the mold 120 separately from the second jig 130.

Although the coupling portion 113 is arranged in the first jig 110 in the description above, the embodiment is not limited thereto. For example, the coupling portion 113 may be arranged in the second jig 130, and the second receiving portion 132 may be disposed on the first jig 110. For example, the coupling portion 113 may be arranged in the mold 120, the first receiving portion 124 may be disposed on the first jig 110, and the second receiving portion 132 may be disposed on the second jig 130. In this case, the coupling portion 113 of the mold 120 may include a first coupling portion (not shown) protruding toward the first jig 110 and a second coupling portion (not shown) protruding toward the second jig 130.

Hereinafter, a method of forming a first protective layer (not shown) and a second protective layer (not shown) will be described in detail.

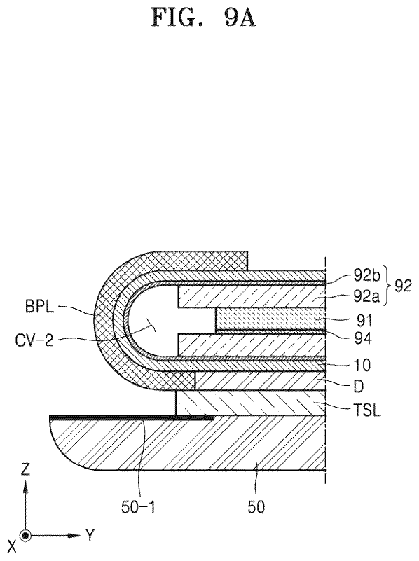

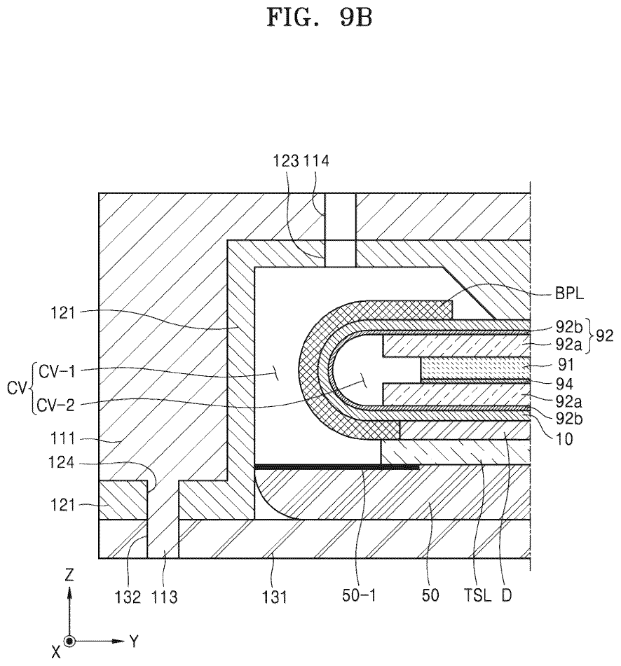

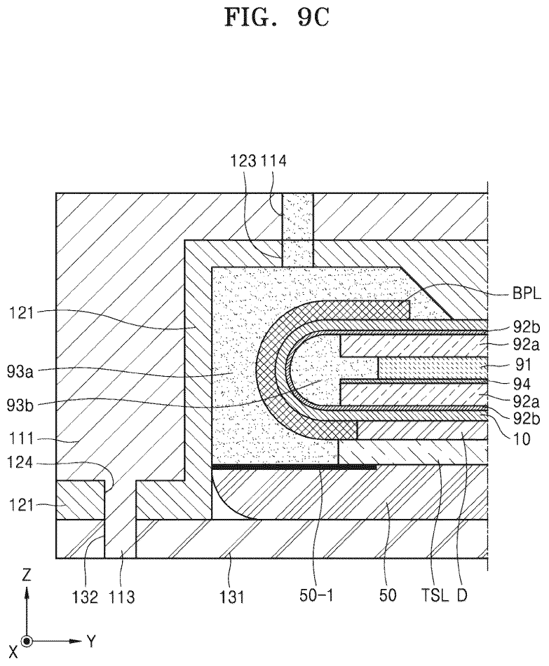

FIGS. 9A to 9C are schematic cross-sectional views illustrating a method of manufacturing a display device according to an embodiment.

Referring to FIGS. 9A to 9C, after a display panel (not shown) is prepared by bending the substrate 10 on which the bending protection layer BPL is disposed, the first jig 110, the mold 120, and the second jig 130 are coupled as described in FIGS. 7 and 8, and then the composition according to the present disclosure may be supplied to the first space CV-1 and the second space CV-2.

Specifically, the composition according to the present disclosure may be introduced into the first space CV-1 through the first injection portion 114 of the first jig 110 and the second injection portion 123 of the mold 120. The first space CV-1 may be defined by at least one portion of each of the mold 120, the second jig 130, the bending protection layer BPL, the touch sensor layer TSL, the display layer D and the substrate 10, or at least one portion of each of the second jig 130, the touch sensor layer TSL, the display layer D and the substrate 10. At this time, the composition may move from a portion of one side of the display panel DP to the other side of the display panel DP. In addition, the composition may be inserted into the second space CV-2 formed by the protection film 92, including the protection film base 92a and the adhesive layer 92b, and the cushion layer 91, arranged in the bending area (not shown) of the display panel DP.

Subsequently, the light source 160 may emit light to the side of the display panel DP from the outside of the first jig 110 and the mold 120. The light may cure the composition disposed in the first space CV-1. The light emitted to the bending area of the display panel DP may cure not only the composition in the first space CV-1 disposed outside the bending area, but also the composition disposed in the second space CV-2. Particularly, in the case as described above, light is hardly blocked by the substrate 10 disposed between the first space CV-1 and the second space CV-2. The light may pass through the substrate 10 and cure the composition inside the second space CV-2.

In the case as described above, the composition disposed in the second space CV-2 may form the second protective layer 93b, and the composition disposed in the first space CV-1 may form the first protective layer 93a. Particularly, the first protective layer 93a may be disposed on the edge of the display panel DP and on the bending protection layer BPL. In addition, the first protective layer 93a may be connected to the second protective layer 93b to be integrated therewith. Specifically, the first protective layer 93a and the second protective layer 93b positioned at the side of the display panel may be connected to each other.

Therefore, the manufacturing apparatus for the display device and the manufacturing method of the display device according to embodiments may form the protective layer simultaneously in the first space CV-1 and the second space CV-2. In addition, the manufacturing apparatus for the display device and the manufacturing method of the display device according to embodiments may reduce the time for forming the protective layer by utilizing light to form the protective layer. The manufacturing apparatus for the display device and the manufacturing method of the display device according to embodiments may not need an excessive energy to be applied in the formation of the protective layer, thereby reducing the damage to various components of the display panel.

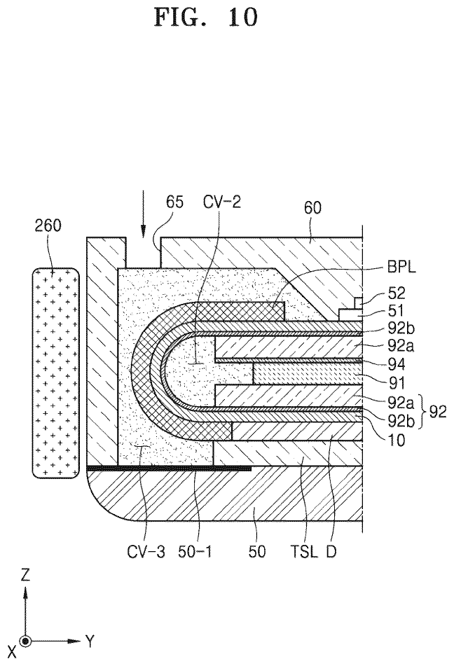

FIG. 10 is a schematic cross-sectional view illustrating a part of a display device according to an embodiment.

Referring to FIG. 10, a display device (not shown) may include a display panel (not shown), a display circuit board 51, a cover member 50, a bracket 60, a main circuit board (not shown), and a lower cover (not shown). In this case, the display panel, the display circuit board 51, the cover member 50, the main circuit board, and the lower cover are similar to those described above in FIGS. 1, 2, 3A, and 3B, and thus detailed descriptions thereof will be omitted.

The bracket 60 may include a third injection portion 65 through which a photocurable resin is injected. The third injection portion 65 may be formed to penetrate the rear surface (e.g., surface facing the lower cover) of the bracket 60. The third injection portion 65 may be connected to a third space CV-3 formed by the display panel, the bracket 60, and the cover member 50. The third space CV-3 may be defined by bending protection layer BPL, the substrate 10 on which the display layer D is disposed, a touch sensor layer disposed on the display layer D, and the bracket 60. At least one third injection portion 65 may be provided. In the case where the third injection portion 65 is provided in plural, a plurality of third injection portions 65 may be spaced apart from each other.

In the case as described above, after manufacturing the display panel DP, the cover member 50 may be attached onto the display panel DP, the display panel DP may be inserted into the bracket 60, and the cover member 50 may be coupled to the bracket 60. The cover member 50 may be coupled to the bracket 60 by a separate resin or a separate adhesive layer. In addition, the display panel DP inserted into the bracket 60 may be in a bent state as depicted in FIG. 10. The display circuit board 51 and the display driver 52 may be attached to the bracket 60 or inserted into the bracket 60.

After the display panel DP is disposed in the bracket 60 as described above, the composition according to the present disclosure may be supplied through the third injection portion 65. In this case, the composition may be injected into the third space CV-3 including an accommodation space (not shown) formed in the bracket 60, and the composition may spread over the entire edge of the display panel DP. Some of the composition may flow into the second space CV-2 and fill the inside of the second space CV-2. The second space CV-2 may be defined by the protection film 92 including the protection film base 92a and the adhesive layer 92b, and the cushion layer 91.

Upon completion of the above-described processes, light is emitted from the outside of the bracket 60 using the light source 260. As the composition and light are similar to those described above in FIGS. 1 to 3 and FIG. 7, detailed descriptions thereof will be omitted.

The bracket 60 may be formed of a transparent material that transmits light. For example, the bracket 60 may include at least one of transparent materials such as polymethyl methacrylate (PMMA), polycarbonate (PC), glass, quartz, and transparent silicon rubber.

As light is transmitted inside of the bracket 60, the first protective layer 93a may be formed between the display panel DP and the bracket 60, and the second protective layer 93b may be formed inside the bending area BA of the display panel DP. In addition, the first protective layer 93a may be connected to the second protective layer 93b.

The first protective layer 93a and the second protective layer 93b included in the display device may reduce the damage to the display panel DP caused by impact applied not only to the bending area of the display panel DP but also to the edge of the display panel DP.

In addition, according to the manufacturing method of the display device, the protective layer may be formed in a quick and simple process.

### EXAMPLES

### Evaluation Example 1. Absorption Spectrum

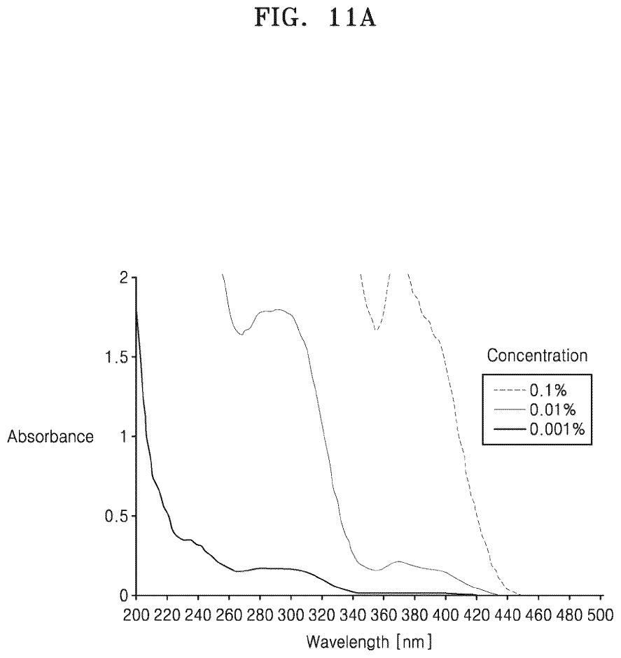

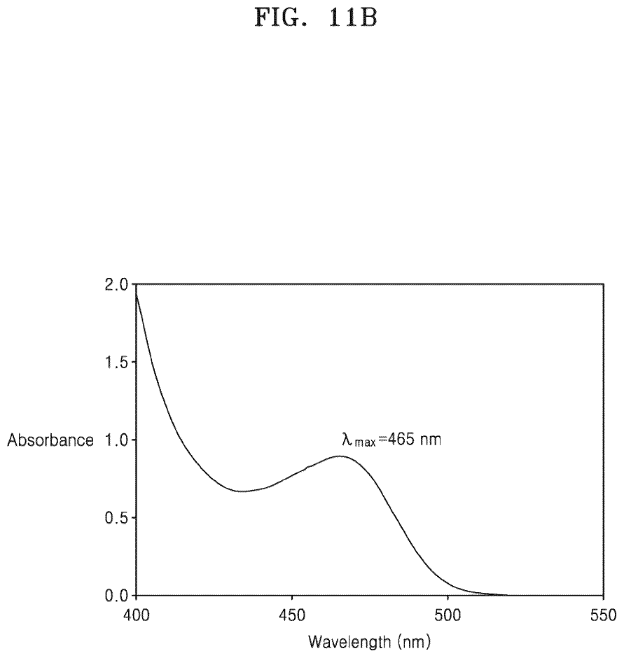

An absorption spectrum of bis(2,4,6-trimethylbenzoyl)phenylphosphine oxide (hereinafter, Comparative Compound 1) and an absorption spectrum of 4DP-IPN (hereinafter, Compound 1) were measured at different concentrations, and the results are shown in FIGS. 11A and 11B, respectively. Referring to FIGS. 11A and 11B, it may be confirmed that absorption of light was observed in a long wavelength region in Compound 1 compared to Comparative Compound 1. That is, it may be confirmed that Compound 1 is an effective initiator in a long wavelength region.

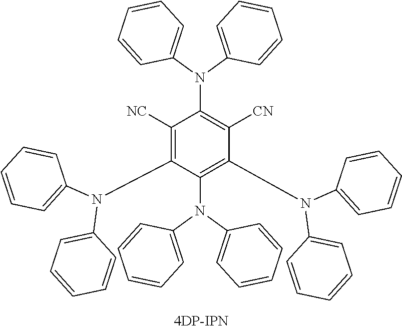 [SMILES: N#Cc1c(N(c2ccccc2)c2ccccc2)c(C#N)c(N(c2ccccc2)c2ccccc2)c(N(c2ccccc2)c2ccccc2)c1N(c1ccccc1)c1ccccc1]

### Preparation of Composition

### 1. Preparation of Comparative Composition 1

5 wt % of bis(2,4,6-trimethylbenzoyl)phenylphosphine oxide, 40 wt % of epoxy acrylate (BIS A GMA) as an oligomer, 25 wt % of 2-hydroxyethyl acrylate (HEA), and 30 wt % of isobornyl acrylate (IBOA) were mixed to prepare a composition.

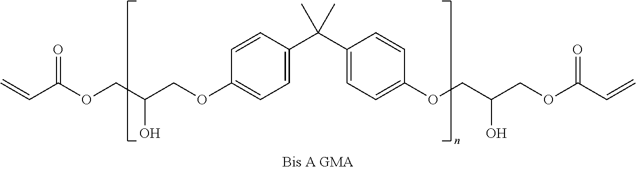

### 2. Preparation of Composition 1

A composition was prepared in the same manner as in the preparation of Comparative Composition 1 above, except that 50 ppm of Compound 1, 600 ppm of Compound 2-4, and 700 ppm of Compound 3-3 were used as the initiator instead of bis(2,4,6-trimethylbenzoyl)phenylphosphine oxide.

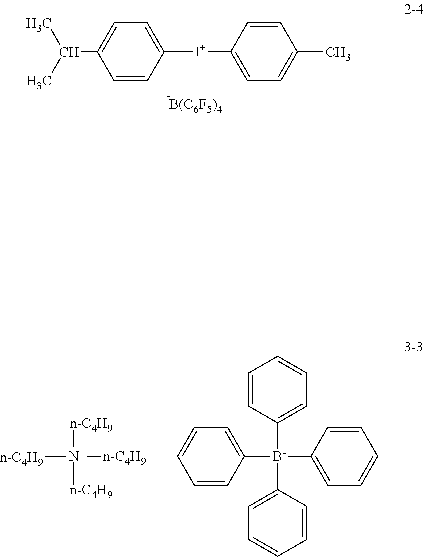

### Evaluation Example 2. Evaluation on Conversion Performance

After applying Comparative Composition 1 and Composition 1 prepared as described above to a substrate in a thickness of 30 μm, a polyimide film (25 μm), each of cured resin sheets of Comparative Composition 1 and Composition 1 (1.1 mm), and a silicon sheet (3 nm) were sequentially stacked. The structure is exposed to light with 450 nm (100 MW/cm²) and 480 nm (120 MW/cm²) for 10 seconds, 30 seconds, and 60 seconds, and the conversion degrees of the formed polymers were measured by FT-IR and shown in Table 1 below.

TABLE 1

| | | 450 nm (100 mW/cm²) | | 480 nm (120 mW/cm²) | |
|---|---|---|---|---|---|
| | Wavelength | Comparative | | Comparative | |
| | Initiator | Compound 1 | Compound 1 | Compound 1 | Compound 1 |
| Light | 10 s | 90.93 | 97.53 | 42.47 | 98.88 |
| exposure | 30 s | 98.39 | 99.76 | 90.25 | 99.18 |
| time | 60 s | 98.98 | 98.62 | 95.46 | 99.07 |

Referring to Table 1, it may be confirmed that the conversion degree of the composition including the initiator (Example 1) according to the present disclosure is higher than that of the composition including the compound of Comparative Example 1 as an initiator.

In the case of the composition including the compound of Comparative Composition 1 as an initiator, it may be seen that the conversion degree decreases at a longer wavelength, indicating that performance of general initiators is insufficient for long wavelengths.

By using the composition according to the present disclosure, the display device having a protective layer on a side and bending area of the display device may be simply and quickly manufactured by using light with a wavelength in the visible light range.

It should be understood that embodiments described herein should be considered in a descriptive sense only and not for purposes of limitation. Descriptions of features or aspects within each embodiment should typically be considered as available for other similar features or aspects in other embodiments. While the present disclosure has been described with reference to the drawings and embodiments thereof, it will be understood by those of ordinary skill in the art that various changes in form and details may be made thereto without departing from the spirit and scope of the present disclosure as set forth and defined by the following claims.

What is claimed is:

1. A composition comprising:
an initiator including a first compound represented by Formula 1 below, a second compound represented by Formula 2 below, and a third compound represented by Formula 3 below; and
an acrylic monomer: 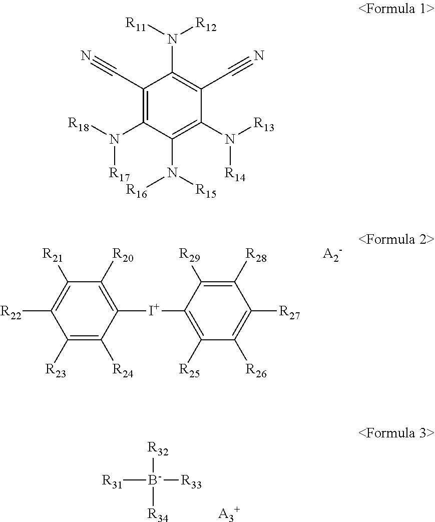
wherein in Formulae 1 to 3,
A₂⁻ is a counter anion,
A₃⁺ is a counter cation,
each of R₁₁ to R₁₈, R₂₀ to R₂₉, and R₃₁ to R₃₄ is independently selected from a group consisting of hydrogen (—H), deuterium (-D), fluorine (—F), chlorine (—Cl), bromine (—Br), iodine (—I), a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁) and —P(═O)(Q₁)(Q₂),
adjacent two or more groups among R₁₁ to R₁₈ are optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ,
adjacent two or more groups among R₂₀ to R₂₉ are optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ, and
adjacent two or more groups among R₃₁ to R₃₄ are optionally combined to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
wherein R₁₀ₐ is selected from a group consisting of:
deuterium, fluorine, chlorine, bromine, iodine, a hydroxyl group, a cyano group or a nitro group;
a C₁-C₆₀ alkyl group, a C₂-C₆₀ alkenyl group, a C₂-C₆₀ alkynyl group, or a C₁-C₆₀ alkoxy group, each of which is unsubstituted or substituted with deuterium, fluorine, chlorine, bromine, iodine, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁) or —P(═O)(Q₁₁)(Q₁₂);
a C₃-C₆₀ carbocyclic group, a C₁-C₆₀ heterocyclic group, a C₆-C₆₀ aryloxy group, or a C₆-C₆₀ arylthio group, each of which is unsubstituted or substituted with deuterium, fluorine, chlorine, bromine, iodine, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁) or —P(═O)(Q₂₁)(Q₂₂); and
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
wherein each of Q₁ to Q₃, Q₁₁ to Q₁₃, Q₂₁ to Q₂₃, and Q₃₁ to Q₃₃ is independently selected from a group consisting of hydrogen, deuterium, fluorine, chlorine, bromine, iodine, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group unsubstituted or substituted with deuterium, fluorine, a cyano group, a C₁-C₆₀ alkyl group, a C₁-C₆₀ alkoxy group, a phenyl group or a biphenyl group, and a C₁-C₆₀ heterocyclic group unsubstituted or substituted with deuterium, fluorine, a cyano group, a C₁-C₆₀ alkyl group, a C₁-C₆₀ alkoxy group, a phenyl group or a biphenyl group.

2. The composition of claim 1, wherein
each of R₁₁ to R₁₈ is independently selected from a group consisting of a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₆-C₆₀ aryl group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, and a monovalent non-aromatic condensed heteropolycyclic group unsubstituted or substituted with at least one R₁₀ₐ.

3. The composition of claim 1, wherein
the first compound is represented by one of Formulae 1-1 and 1-2 below,
<Formula 1-1> 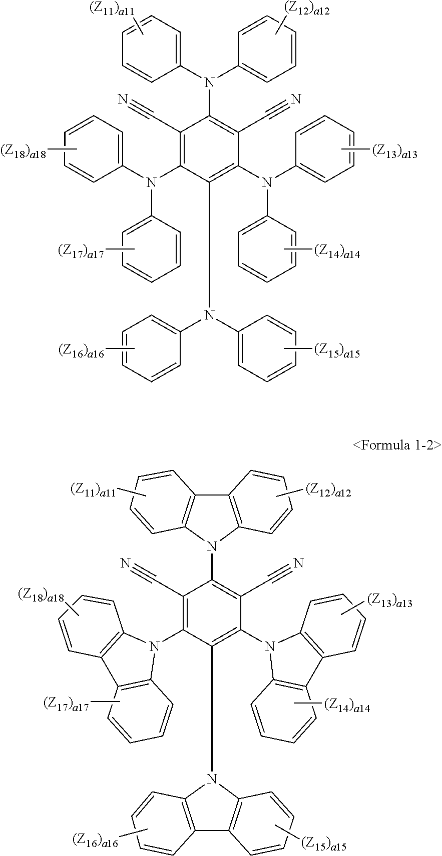
wherein in Formulae 1-1 and 1-2,
each of Z₁₁ to Z₁₈ is independently selected from a group consisting of hydrogen and R₁₀ₐ, and
each of a11 to a18 is an integer from 1 to 4.

4. The composition of claim 1, wherein
each of R₂₀ to R₂₉ is independently selected from a group consisting of hydrogen, deuterium, fluorine, chlorine, bromine, iodine, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, and a C₁-C₆₀ alkoxy group unsubstituted or substituted with at least one R₁₀ₐ.

5. The composition of claim 1, wherein A₂⁻ comprises a fluorine atom.

6. The composition of claim 1, wherein
each of R₃₁ to R₃₄ is independently selected from a group consisting of a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₆-C₆₀ aryl group unsubstituted or substituted with at least one R₁₀ₐ, and a C₁-C₆₀ heteroaryl group unsubstituted or substituted with at least one R₁₀ₐ.

7. The composition of claim 1, wherein
A₃⁺ is Na⁺, [P(R₃₁ₐ)(R_{31b})(R_{31c})(R_{31d})]⁺ or [N(R₃₂ₐ)(R_{32b})(R_{32c})(R_{32d})]⁺,
each of R₃₁ₐ, R_{31b}, R_{31c}, R_{31d}, R₃₂ₐ, R_{32b}, R_{32c} and R_{32d} is independently selected from a group consisting of a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, and a C₁-C₆₀ heterocyclic group unsubstituted or substituted with at least one R₁₀ₐ.

8. The composition of claim 1, wherein a concentration of the first compound is more than 0 ppm and equal to or less than 500 ppm.

9. The composition of claim 1, wherein
a concentration of the second compound is equal to or more than 500 ppm and equal to or less than 10,000 ppm, and
a concentration of the third compound is equal to or more than 500 ppm and equal to or less than 10,000 ppm.

10. The composition of claim 1, wherein a cured product is formed when light is emitted onto the composition.

11. The composition of claim 10, wherein
a peak top wavelength of the irradiated light is in a range from about 450 nm to about 500 nm.

12. The composition of claim 10, wherein
a Young's ratio of the cured product is equal to or more than 200 MPa to 3,000 MPa, an elongation of the cured product is in a range from about 5% to about 100%, and a glass transition temperature T_{g} is in a range from about 20° C. to about 100° C.

13. A display device comprising a display panel,
wherein the display panel comprises:
a substrate including a first area, a second area, and a bending area connecting the first area to the second area and being bent;
a first protective layer disposed on at least one portion of an edge of the substrate; and
a second protective layer disposed inside a bent portion of the substrate,
wherein the first protective layer and the second protective layer comprise a composition including an initiator including a first compound represented by Formula 1 below, a second compound represented by Formula 2 below, and a third compound represented by Formula 3 below, and an acrylic monomer, 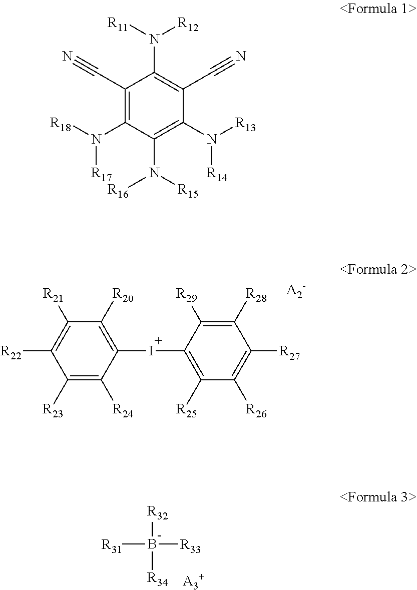
wherein in Formulae 1 to 3,
A₂⁻ is a counter anion,
A₃⁺ is a counter cation,
each of R₁₁ to R₁₈, R₂₀ to R₂₉, and R₃₁ to R₃₄ is independently selected from a group consisting of hydrogen (—H), deuterium (-D), fluorine (—F), chlorine (—Cl), bromine (—Br), iodine (—I), a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁) and —P(═O)(Q₁)(Q₂),
adjacent two or more groups among R₁₁ to R₁₈ are optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ,
adjacent two or more groups among R₂₀ to R₂₉ are optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ, and
adjacent two or more groups among R₃₁ to R₃₄ are optionally combined to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
wherein R₁₀ₐ is selected from a group consisting of:
deuterium, fluorine, chlorine, bromine, iodine, a hydroxyl group, a cyano group or a nitro group;
a C₁-C₆₀ alkyl group, a C₂-C₆₀ alkenyl group, a C₂-C₆₀ alkynyl group, or a C₁-C₆₀ alkoxy group, each of which is unsubstituted or substituted with deuterium, fluorine, chlorine, bromine, iodine, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁) or —P(═O)(Q₁₁)(Q₁₂);
a C₃-C₆₀ carbocyclic group, a C₁-C₆₀ heterocyclic group, a C₆-C₆₀ aryloxy group, or a C₆-C₆₀ arylthio group, each of which is unsubstituted or substituted with deuterium, fluorine, chlorine, bromine, iodine, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁) or —P(═O)(Q₂₁)(Q₂₂); and
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
wherein each of Q₁ to Q₃, Q₁₁ to Q₁₃, Q₂₁ to Q₂₃, and Q₃₁ to Q₃₃ is independently selected from a group consisting of hydrogen, deuterium, fluorine, chlorine, bromine, iodine, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group unsubstituted or substituted with deuterium, fluorine, a cyano group, a C₁-C₆₀ alkyl group, a C₁-C₆₀ alkoxy group, a phenyl group or a biphenyl group, and a C₁-C₆₀ heterocyclic group unsubstituted or substituted with deuterium, fluorine, a cyano group, a C₁-C₆₀ alkyl group, a C₁-C₆₀ alkoxy group, a phenyl group or a biphenyl group.

14. The display device of claim 13, wherein
the composition is cured by light with a peak top wavelength in a range from about 450 nm to about 500 nm.

15. The display device of claim 13, further comprising a bracket into which the display panel is inserted.

16. The display device of claim 15, wherein
the bracket has an injection hole through which the composition is injected.

17. A method of manufacturing a display device, the method comprising:
disposing a first jig and a mold on the display panel to form a space adjacent to at least one edge of the display panel;
supplying a composition into the space; and
curing the composition by irradiating light with a peak top wavelength in a range from about 450 nm to about 530 nm,
wherein the composition includes an initiator including a first compound represented by Formula 1 below, a second compound represented by Formula 2 below, and a third compound represented by Formula 3 below, and an acrylic monomer, 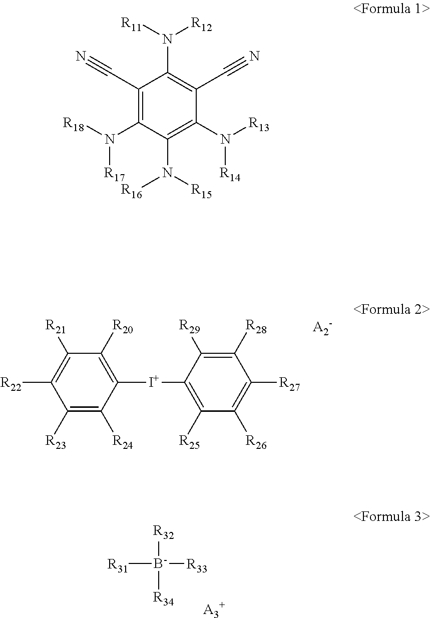
wherein in Formulae 1 to 3,
A₂⁻ is a counter anion,
A₃⁺ is a counter cation,
each of R₁₁ to R₁₈, R₂₀ to R₂₉, and R₃₁ to R₃₄ is independently selected from a group consisting of hydrogen (—H), deuterium (-D), fluorine (—F), chlorine (—Cl), bromine (—Br), iodine (—I), a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁) and —P(═O)(Q₁)(Q₂),
adjacent two or more groups among R₁₁ to R₁₈ are optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ,
adjacent two or more groups among R₂₀ to R₂₉ are optionally combined to each other to form a C₅-C₃₀ carbocyclic group unsubstituted or substituted with at least one R₁₀ₐ, or a C₁-C₃₀ heterocyclic group unsubstituted or substituted with at least one R₁₀ₐ, and
adjacent two or more groups among R₃₁ to R₃₄ are optionally combined to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
wherein R₁₀ₐ is selected from a group consisting of:
deuterium, fluorine, chlorine, bromine, iodine, a hydroxyl group, a cyano group or a nitro group;
a C₁-C₆₀ alkyl group, a C₂-C₆₀ alkenyl group, a C₂-C₆₀ alkynyl group, or a C₁-C₆₀ alkoxy group, each of which is unsubstituted or substituted with deuterium, fluorine, chlorine, bromine, iodine, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁) or —P(═O)(Q₁₁)(Q₁₂);
a C₃-C₆₀ carbocyclic group, a C₁-C₆₀ heterocyclic group, a C₆-C₆₀ aryloxy group, or a C₆-C₆₀ arylthio group, each of which is unsubstituted or substituted with deuterium, fluorine, chlorine, bromine, iodine, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁) or —P(═O)(Q₂₁)(Q₂₂); and
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
wherein each of Q₁ to Q₃, Q₁₁ to Q₁₃, Q₂₁ to Q₂₃, and Q₃₁ to Q₃₃ is independently selected from a group consisting of hydrogen, deuterium, fluorine, chlorine, bromine, iodine, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group unsubstituted or substituted with deuterium, fluorine, a cyano group, a C₁-C₆₀ alkyl group, a C₁-C₆₀ alkoxy group, a phenyl group or a biphenyl group, and a C₁-C₆₀ heterocyclic group unsubstituted or substituted with deuterium, fluorine, a cyano group, a C₁-C₆₀ alkyl group, a C₁-C₆₀ alkoxy group, a phenyl group or a biphenyl group.

18. The method of claim 17, wherein the light is irradiated to a side of the display panel.

19. The method of claim 17, further comprising
injecting the composition into a second space between a bending portion of the display panel and a cushion layer of the display panel facing the bending portion.

20. The method of claim 17, wherein
the composition injected into the space adjacent to at least one edge of the display panel and the composition injected into a second space between a bending portion of the display panel and a cushion layer of the display panel facing the bending portion are connected to each other after being cured.
